(19) United States
(12) Patent Application Publication
(10) Pub. No.: US 2025/0351576 A1
(43) Pub. Date: Nov. 13, 2025

(54) DISPLAY DEVICE AND METHOD OF PRODUCING DISPLAY DEVICE

(71) Applicant: Sharp Display Technology Corporation, Kameyama City (JP)

(72) Inventors: Kengo HARA, Kameyama City (JP); Hajime IMAI, Kameyama City (JP); Tatsuya KAWASAKI, Kameyama City (JP); Yohei TAKEUCHI, Kameyama City (JP); Masafumi SUGINO, Kameyama City (JP)

(21) Appl. No.: 19/173,115

(22) Filed: Apr. 8, 2025

(30) Foreign Application Priority Data
May 13, 2024 (JP) 2024-078123

(51) Int. Cl. H10D 86/40; G02F 1/1343; G02F 1/1362; G02F 1/1368; G06F 3/041; G06F 3/044; H10D 86/01

(52) U.S. Cl. CPC H10D 86/451; G02F 1/134309; G02F 1/136286; G02F 1/1368; H10D 86/0231; H10D 86/441; G06F 3/0412; G06F 3/044; G06F 2203/04103

(57) ABSTRACT

In a display device, a switching component includes a first electrode being a portion of a first conductive film, a semiconductor section being a portion of a semiconductor film disposed above the first conductive film via a first insulating film, a second electrode being a portion of a second conductive film disposed above the semiconductor film, and a third electrode being a portion of the second conductive film. A first line is a portion of a third conductive film disposed above the second conductive film via a second insulating film. A first terminal includes a first terminal portion being a portion of the second conductive film and a second terminal portion being a portion of the third conductive film. The second insulating film includes a contact hole overlapping the first line and the second electrode and a contact hole overlapping the first and second terminal portions.

### CROSS REFERENCE TO RELATED APPLICATION

This application claims priority from Japanese Patent Application No. 2024-078123 filed on May 13, 2024. The entire contents of the priority application are incorporated herein by reference.

### TECHNICAL FIELD

The present technology described herein relates to a display device and a method of producing a display device with which the number of times a second insulating film is processed is reduced.

### BACKGROUND

One example of known display devices has a following configuration. Such a display device includes an active matrix substrate that includes a substrate, and a first conductive layer, a second conductive layer, and an organic insulating film on the substrate. In such an active matrix substrate, the first conductive layer and the second conductive layer partially overlap and the organic insulating film is farther away from the substrate than the first conductive layer and the second conductive layer are, and one of the first conductive layer and the second conductive layer that is farther away from the substrate is in contact with the organic insulating film via an inorganic insulating film.

Such a display device includes a first source layer as the first conductive layer, a second source layer as the second conductive layer, a second inorganic insulating film as the inorganic insulating film, and a first inorganic insulating film that is disposed between the first source layer and the second source layer. More in detail, in the areas of the active matrix substrate where the TFT components and the pixel electrodes are disposed, the first inorganic insulating film has openings corresponding to the drain electrodes, which are portions of the first source layer, and the first source layer and the second source layer are electrically connected via the openings.

### SUMMARY

Components for supplying various kinds of signals (such as a driver and a flexible substrate) are mounted in the edge area of the active matrix substrate and terminal portions to be connected to the components are disposed in the area. The terminal portion includes a gate layer and a conductive member that are connected. The gate insulating layer, the first inorganic insulating film, the second inorganic insulating film, and the organic insulating film that are disposed between the gate layer and the conductive member include openings, which communicate with each other, to connect the gate layer and the conductive member. Therefore, in producing the active matrix substrate, at least the process of forming the openings in the first inorganic insulating film corresponding to the areas where the TFT components and the pixel electrodes are formed and the process of collectively forming openings in the gate insulating film, the first inorganic insulating film, the second inorganic film, and the organic film need to be performed. This increases the number of times the first inorganic insulating film is processed and the processing time becomes longer. Particularly, with the first inorganic insulating film being thick, the number of times the first inorganic insulating film is processed is greatly increased and the processing time tends to become much longer.

The technology described herein was made in view of the above circumstances. An object is to reduce the number of times a second insulating film is processed.
(1) A display device according to the technology described herein includes a display section in which an image is displayed, a non-display section in which no image is displayed, a switching component disposed in the display section, a first line disposed in the display section and connected to the switching component, and a first terminal disposed in the non-display section. The switching component includes a first electrode that is a portion of a first conductive film, a semiconductor section that is a portion of a semiconductor film disposed in a layer upper than the first conductive film via a first insulating film and is disposed to overlap the first electrode, a second electrode that is a portion of a second conductive film disposed in a layer upper layer than the semiconductor film and is connected to the semiconductor section, and a third electrode that is a portion of the second conductive film different from the portion of the second conductive film configured as the second electrode and is connected to the semiconductor section. The first line is a portion of a third conductive film disposed in a layer upper than the second conductive film via a second insulating film and a portion of the first line overlaps the second electrode. The first terminal includes a first terminal portion and a second terminal portion. The first terminal portion is a portion of the second conductive film different from portions of the second conductive film configured as the second electrode and the third electrode. The second terminal portion is a portion of the third conductive film different from the portion of the third conductive film configured as the first line and at least a portion of the second terminal portion overlaps the first terminal portion. The second insulating film includes a first contact hole that overlaps the first line and the second electrode and a second contact hole that overlaps the first terminal portion and the second terminal portion.
(2) The display device may further include, in addition to (1), a second line that is disposed in the display section and is a portion of the second conductive film different from portions of the second conductive film configured as the second electrode, the third electrode, and the first terminal portion. The second line may be continuous to the second electrode, and the second line may extend along the first line and overlap the first line via the second insulating film.
(3) The display device may further include, in addition to (1), a third line that is disposed in the display section and is a portion of the first conductive film different from the portion of the first conductive film configured as the first electrode. The third line may be continuous to the first electrode and cross the first line via the first insulating film and the second insulating film.
(4) The display device may further include, in addition to any one of (1) to (3), a fourth electrode disposed in the display section and connected to the third electrode and a pixel electrode disposed in the display section and connected to the fourth electrode. The fourth electrode may be a portion of the third conductive film different from the portion of the third conductive film configured as the first line and at least a portion of the fourth electrode may overlap the third electrode. The pixel electrode may be a portion of a fourth conductive film that is disposed in a layer upper than the third conductive film via a third insulating film and a portion of the pixel electrode may overlap the fourth electrode. The second insulating film may include a third contact hole that overlaps the third electrode and the fourth electrode. The third insulating film may include a fourth contact hole that overlaps the fourth electrode and the pixel electrode.
(5) The display device may further include, in addition to any one of (1) to (3), a pixel electrode disposed in the display section and connected to the third electrode. The pixel electrode may be a portion of a fourth conductive film that is disposed in a layer upper than the third conductive film via a third insulating film and a portion of the pixel electrode may overlap the third electrode. The second insulating film and the third insulating film may include a fifth contact hole that overlaps the third electrode and the pixel electrode.
(6) A display device according to the technology described herein includes a display section in which an image is displayed, a non-display section in which no image is displayed, a switching component disposed in the display section, a first line disposed in the display section and connected to the switching component, a pixel electrode disposed in the display section and connected to the switching component, a common electrode disposed in the display section, and a second terminal disposed in the non-display section. The switching component includes a first electrode that is a portion of a first conductive film, a semiconductor section that is a portion of a semiconductor film disposed in a layer upper than the first conductive film via a first insulating film and is disposed to overlap the first electrode, a second electrode that is a portion of a second conductive film disposed in a layer upper layer than the semiconductor film and is connected to the semiconductor section, and a third electrode that is a portion of the second conductive film different from the portion of the second conductive film configured as the second electrode and is connected to the semiconductor section. The first line is a portion of a third conductive film that is disposed in a layer upper than the second conductive film via a second insulating film and a portion of the first line overlaps the second electrode. The pixel electrode is a portion of a fourth conductive film that is disposed in a layer upper than the third conductive film via a third insulating film and a portion of the pixel electrode overlaps the third electrode and the pixel electrode is connected to the third electrode. The common electrode is a portion of a fifth conductive film that is disposed in a layer upper than the fourth conductive film via a fourth insulating film and the common electrode overlaps the pixel electrode via the fourth insulating film. The second terminal includes a third terminal portion and a fourth terminal portion. The third terminal portion is a portion of the third conductive film different from the portion of the third conductive film configured as the first line. The fourth terminal portion is a portion of the fifth conductive film different from the portion of the fifth conductive film configured as the common electrode and at least a portion of the fourth terminal portion overlaps the third terminal portion. The second insulating film includes a first contact hole that overlaps the first line and the second electrode. The third insulating film and the fourth insulating film include a sixth contact hole that overlaps the third terminal portion and the fourth terminal portion.
(7) A display device according to the technology described herein includes a display section in which an image is displayed, a non-display section in which no image is displayed, a switching component disposed in the display section, a first line disposed in the display section and connected to the switching component, a pixel electrode disposed in the display section and connected to the switching component, a common electrode disposed in the display section, and a third terminal disposed in the non-display section. The switching component includes a first electrode that is a portion of a first conductive film, a semiconductor section that is a portion of a semiconductor film disposed in a layer upper than the first conductive film via a first insulating film and is to overlap the first electrode, a second electrode that is a portion of a second conductive film disposed in a layer upper layer than the semiconductor film and is connected to the semiconductor section, and a third electrode that is a portion of the second conductive film different from the portion of the second conductive film configured as the second electrode and is connected to the semiconductor section. The first line is a portion of a third conductive film disposed in a layer upper than the second conductive film via a second insulating film and a portion of the first line overlaps the second electrode. The pixel electrode is a portion of a fourth conductive film that is disposed in a layer upper than the third conductive film via a third insulating film. The common electrode is a portion of a fifth conductive film that is disposed in a layer upper than the fourth conductive film via a fourth insulating film and the common electrode overlaps the pixel electrode via the fourth insulating film. The third terminal includes a fifth terminal portion and a sixth terminal portion. The fifth terminal portion is a portion of the fourth conductive film different from the portion of the fourth conductive film configured as the pixel electrode. The sixth terminal portion is a portion of the fifth conductive film different from the portion of the fifth conductive film configured as the common electrode and at least a portion of the sixth terminal portion overlaps the fifth terminal portion. The second insulating film includes a first contact hole that overlaps the first line and the second electrode. The fourth insulating film includes a seventh contact hole that overlaps the fifth terminal portion and the sixth terminal portion.
(8) A method of producing a display device according to the technology described herein includes forming a first conductive film, patterning the first conductive film to form a first electrode in a display section in which an image is displayed, forming a first insulating film in a layer upper than the first conductive film, forming a semiconductor film in a layer upper than the first insulating film, patterning the semiconductor film to form a semiconductor section that overlaps the first electrode, forming a second conductive film in a layer upper than the semiconductor film, patterning the second conductive film to form a second electrode connected to the semiconductor section and a third electrode connected to the semiconductor section and form a first terminal portion in a non-display section in which no image is displayed, forming a second insulating film in a layer upper than the second conductive film, patterning the second insulating film to form a first contact hole that overlaps the second electrode and a second contact hole that overlaps the first terminal portion, forming a third conductive film in a layer upper than the second insulating film, and patterning the third conductive film to form a first line in the display section such that a portion of the first line overlaps the second electrode and the first contact hole and to form a second terminal portion in the non-display section such that at least a portion of the second terminal portion overlaps the first terminal portion and the second contact hole, and the second terminal portion and the first terminal portion being configured as a first terminal.

According to the technology described herein, the number of times the second insulating film is processed is reduced.

### BRIEF DESCRIPTION OF THE DRAWINGS

FIG. 1 is a plan view illustrating a liquid crystal panel included in a liquid crystal display device according to a first embodiment.

FIG. 2 is a cross-sectional view schematically illustrating the liquid crystal panel according to the first embodiment.

FIG. 3 is a plan view illustrating a display area of an array substrate of the liquid crystal panel according to the first embodiment.

FIG. 4 is a cross-sectional view illustrating a portion of the array substrate including a pixel electrode according to the first embodiment.

FIG. 5 is a plan view illustrating pixel arrangement of the array substrate according to the first embodiment.

FIG. 6 is a cross-sectional view of the array substrate according to the first embodiment along vi-vi line in FIG. 5.

FIG. 7 is a plan view illustrating a configuration of a portion of the array substrate including a driver arrangement area according to the first embodiment.

FIG. 8 is a bottom view of a driver according to the first embodiment.

FIG. 9 is a cross-sectional view illustrating terminals of the array substrate and bumps of the driver that are connected.

FIG. 10 is a cross-sectional view of a portion of the array substrate including a first terminal according to the first embodiment.

FIG. 11 is a cross-sectional view of a terminal of a reference example.

FIG. 12A is a cross-sectional view along vi-vi line in FIG. 5 illustrating a first metal film that is patterned in a first step of a method of producing the array substrate according to the first embodiment.

FIG. 12B is a cross-sectional view along vi-vi line in FIG. 5 illustrating a semiconductor film that is patterned in a second step of the method of producing the array substrate according to the first embodiment.

FIG. 12C is a cross-sectional view along vi-vi line in FIG. 5 illustrating a second metal film that is patterned in a fourth step of the method of producing the array substrate according to the first embodiment.

FIG. 13A is a cross-sectional view illustrating a portion corresponding to the portion of FIG. 10 and the first metal film that is patterned in the first step of a method of producing the array substrate according to the first embodiment.

FIG. 13B is a cross-sectional view illustrating a portion corresponding to the portion of FIG. 10 and the semiconductor film that is patterned in the second step of the method of producing the array substrate according to the first embodiment.

FIG. 13C is a cross-sectional view illustrating a portion corresponding to the portion of FIG. 10 and the second metal film that is patterned in the fourth step of the method of producing the array substrate according to the first embodiment.

FIG. 14A is a cross-sectional view illustrating a patterned first metal film according to the reference example.

FIG. 14B is a cross-sectional view illustrating a patterned semiconductor film according to the reference example.

FIG. 14C is a cross-sectional view illustrating a patterned gate insulating film according to the reference example.

FIG. 14D is a cross-sectional view illustrating a patterned second metal film according to the reference example.

FIG. 15A is a cross-sectional view along vi-vi line in FIG. 5 illustrating a first interlayer insulating film that is patterned in a fifth step of the method of producing the array substrate according to the first embodiment.

FIG. 15B is a cross-sectional view along vi-vi line in FIG. 5 illustrating a third metal film that is patterned in a sixth step of the method of producing the array substrate according to the first embodiment.

FIG. 15C is a cross-sectional view along vi-vi line in FIG. 5 illustrating a planarizing film that is patterned in a seventh step of the method of producing the array substrate according to the first embodiment.

FIG. 16A is a cross-sectional view illustrating a portion corresponding to the portion of FIG. 10 and the first interlayer insulating film that is patterned in the fifth step of the method of producing the array substrate according to the first embodiment.

FIG. 16B is a cross-sectional view illustrating a portion corresponding to the portion of FIG. 10 and the third metal film that is patterned in the sixth step of the method of producing the array substrate according to the first embodiment.

FIG. 16C is a cross-sectional view illustrating a portion corresponding to the portion of FIG. 10 and the planarizing film that is patterned in the seventh step of the method of producing the array substrate according to the first embodiment.

FIG. 17A is a cross-sectional view illustrating a patterned first interlayer insulating film according to the reference example.

FIG. 17B is a cross-sectional view illustrating a patterned third metal film according to the reference example.

FIG. 17C is a cross-sectional view illustrating a patterned planarizing film according to the reference example.

FIG. 18A is a cross-sectional view along vi-vi line in FIG. 5 illustrating a second interlayer insulating film that is patterned in an eighth step of the method of producing the array substrate according to the first embodiment.

FIG. 18B is a cross-sectional view along vi-vi line in FIG. 5 illustrating a first transparent electrode film and a fourth metal film that are patterned in a ninth step of the method of producing the array substrate according to the first embodiment.

FIG. 18C is a cross-sectional view along vi-vi line in FIG. 5 illustrating the fourth metal film that is patterned in a tenth step of the method of producing the array substrate according to the first embodiment.

FIG. 19A is a cross-sectional view illustrating a portion corresponding to the portion of FIG. 10 and the second interlayer insulating film that is patterned in the eighth step of the method of producing the array substrate according to the first embodiment.

FIG. 19B is a cross-sectional view illustrating a portion corresponding to the portion of FIG. 10 and the first transparent electrode film and the fourth metal film that are patterned in the ninth step of the method of producing the array substrate according to the first embodiment.

FIG. 19C is a cross-sectional view illustrating a portion corresponding to the portion of FIG. 10 and the fourth metal film that is patterned in the tenth step of the method of producing the array substrate according to the first embodiment.

FIG. 20A is a cross-sectional view illustrating a patterned second interlayer insulating film according to the reference example.

FIG. 20B is a cross-sectional view illustrating a first transparent electrode film and a fourth metal film that are patterned according to the reference example.

FIG. 20C is a cross-sectional view illustrating a patterned fourth metal film according to the reference example.

FIG. 21A is a cross-sectional view along vi-vi line in FIG. 5 illustrating a third interlayer insulating film that is patterned in an eleventh step of the method of producing the array substrate according to the first embodiment.

FIG. 21B is a cross-sectional view along vi-vi line in FIG. 5 illustrating a second transparent electrode film that is patterned in a twelfth step of the method of producing the array substrate according to the first embodiment.

FIG. 22A is a cross-sectional view illustrating a portion corresponding to the portion of FIG. 10 and the third interlayer insulating film that is patterned in the eleventh step of the method of producing the array substrate according to the first embodiment.

FIG. 22B is a cross-sectional view illustrating a portion corresponding to the portion of FIG. 10 and the second transparent electrode film that is patterned in the twelfth step of the method of producing the array substrate according to the first embodiment.

FIG. 23A is a cross-sectional view illustrating a patterned third interlayer insulating film according to the reference example.

FIG. 23B is a cross-sectional view illustrating a patterned second transparent electrode film according to the reference example.

FIG. 24 is a plan view illustrating pixel arrangement of an array substrate according to a second embodiment.

FIG. 25 is a cross-sectional view of the array substrate according to the second embodiment along xxv-xxv line in FIG. 24.

FIG. 26 is a cross-sectional view of the array substrate according to the second embodiment along xxvi-xxvi line in FIG. 24.

FIG. 27 is a cross-sectional view along corresponding vi-vi line in FIG. 5 illustrating an array substrate according to a third embodiment.

FIG. 28A is a cross-sectional view along corresponding vi-vi line in FIG. 5 illustrating the first interlayer insulating film that is patterned in the fifth step of the method of producing the array substrate according to the third embodiment.

FIG. 28B is a cross-sectional view along corresponding vi-vi line in FIG. 5 illustrating the third metal film that is patterned in the sixth step of the method of producing the array substrate according to the third embodiment.

FIG. 28C is a cross-sectional view along corresponding vi-vi line in FIG. 5 illustrating the planarizing film that is patterned in the seventh step of the method of producing the array substrate according to the third embodiment.

FIG. 29A is a cross-sectional view along corresponding vi-vi line in FIG. 5 illustrating the first interlayer insulating film and the second interlayer insulating film that are patterned in the eighth step of the method of producing the array substrate according to the third embodiment.

FIG. 29B is a cross-sectional view along corresponding vi-vi line in FIG. 5 illustrating the first transparent electrode film and the fourth metal film that are patterned in the ninth step of the method of producing the array substrate according to the third embodiment.

FIG. 29C is a cross-sectional view along corresponding vi-vi line in FIG. 5 illustrating the fourth metal film that is patterned in the tenth step of the method of producing the array substrate according to the third embodiment.

FIG. 30 is a cross-sectional view of a portion of an array substrate including a first terminal according to a fourth embodiment.

FIG. 31 is a cross-sectional view illustrating an extending line that is a portion of the second metal film and connected to the first terminal according to the fourth embodiment.

FIG. 32 is a cross-sectional view illustrating an extending line that is a portion of the first metal film and connected to the first terminal according to the fourth embodiment.

FIG. 33 is a cross-sectional view of a portion of an array substrate including a first terminal according to a fifth embodiment.

FIG. 34 is a cross-sectional view illustrating an extending line that is a portion of the third metal film and connected to the first terminal according to the fifth embodiment.

FIG. 35 is a cross-sectional view illustrating an extending line that is a portion of the second metal film and connected to the first terminal according to the fourth embodiment.

FIG. 36 is a cross-sectional view illustrating an extending line that is a portion of the first metal film and connected to the first terminal according to the fourth embodiment.

FIG. 37 is a cross-sectional view of a portion of an array substrate including a second terminal according to a sixth embodiment.

FIG. 38 is a cross-sectional view of the array substrate according to the sixth embodiment along xxxviii-xxxviii line in FIG. 37.

FIG. 39 is a cross-sectional view of a portion of an array substrate including a third terminal according to a seventh embodiment.

FIG. 40 is a cross-sectional view of the array substrate according to the seventh embodiment along xxxx-xxxx line in FIG. 39.

### DETAILED DESCRIPTION

### First Embodiment

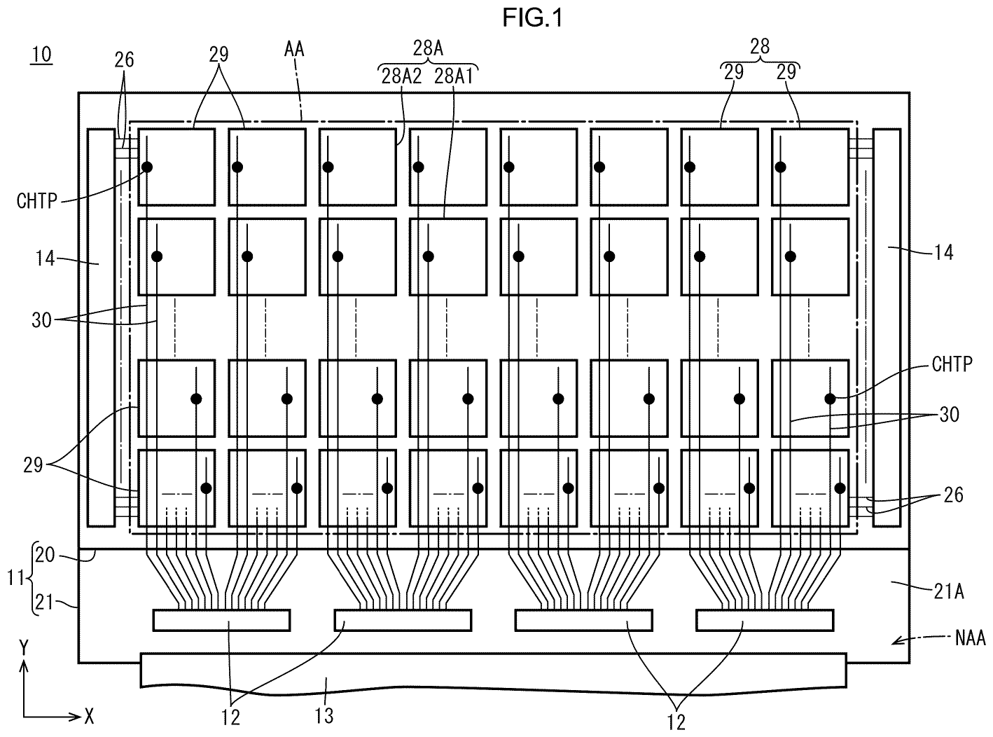

A first embodiment will be described with reference to FIGS. 1 to 23B. In this embodiment section, a liquid crystal display apparatus 10 having a display function and a touch panel function (position input function) will be described. X-axes, Y-axes, and Z-axes may be present in the drawings. The axes in each drawing correspond to the respective axes in other drawings.

As illustrated in FIG. 1, the liquid crystal display apparatus 10 at least includes a liquid crystal panel 11 (a display device, a display panel) that has a laterally long rectangular plan view shape and displays an image and a backlight unit (a lighting device) that is an external light source and supplies light to the liquid crystal panel 11 for displaying. The backlight unit is disposed behind (on a back surface side of) the liquid crystal panel 11. The backlight unit includes light sources configured to emit white light (e.g., LEDs) and optical members for converting the light from the light sources into planar light by applying optical effects to the light from the light sources. A middle section of a plate surface of the liquid crystal panel 11 is configured as a display area AA (a display section) in which images are displayed. An outer section in a frame shape surrounding the display area AA on the plate surface of the liquid crystal panel 11 is configured as a non-display area NAA (a non-display section) in which the images are not displayed.

As illustrated in FIG. 1, circuit portions 14 (a surrounding circuit portion, a gate circuit) are disposed in the non-display area NAA of the liquid crystal panel 11. A pair of circuit portions 14 are disposed to sandwich the display area AA with respect to the X-axis direction. The circuit portion 14 is disposed in a belt shape area extending in the Y-axis direction. The circuit portions 14 are for supplying scan signals to gate lines 26, which will be described later, and are monolithically fabricated on the array substrate 21. The circuit portion 14 is a gate driver monolithic (GDM) circuit. The circuit portion 14 includes a shift resister circuit that is configured to output a scanning signal at a predefined timing and a buffer circuit that is configured to amplify scanning signals.

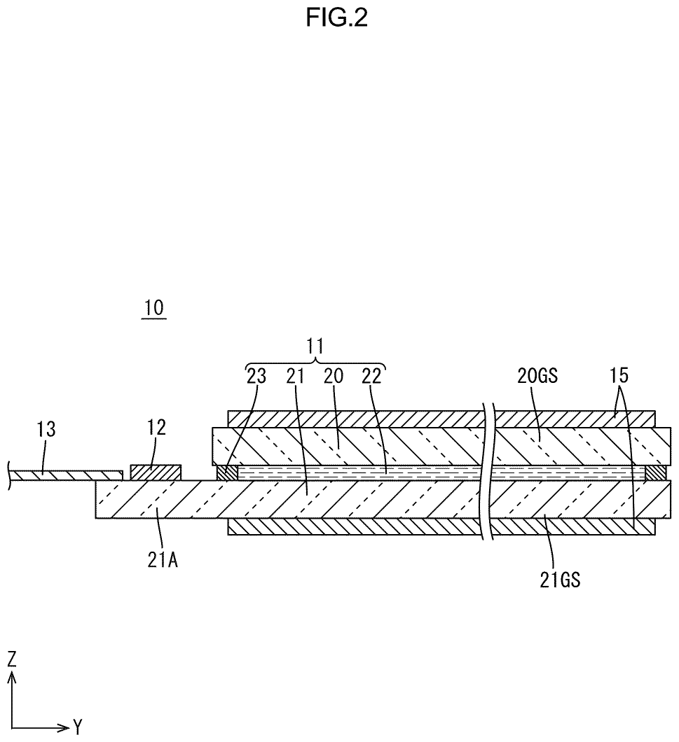

The liquid crystal panel 11 will be described in detail with reference to FIGS. 1 and 2. As illustrated in FIGS. 1 and 2, the liquid crystal panel 11 includes a pair of substrates 20, 21 that are bonded to each other. One of the substrates 20, 21 on the front side (a front surface side) is an opposed substrate 20 (a CF substrate, a second substrate) and another one on the back side (a rear surface side) is an array substrate 21 (an active matrix substrate, a first substrate). The opposed substrate 20 and the array substrate 21 include glass substrates 20GS, 21GS (substrate) and various kinds of films that are formed in layers on an inner surface side of the glass substrates. A liquid crystal layer 22 (a medium layer) is disposed between the substrates 20 and 21. The liquid crystal layer 22 includes liquid crystal molecules having optical characteristics that vary according to application of electric field. A sealing portion 23 is disposed between the outer peripheral portions of the substrates 20, 21 for sealing the liquid crystal layer 22. The sealing portion 23 is formed in a square frame shape (an endless ring shape) and surrounds the liquid crystal layer 22. Polarizing plates 15 are attached to outer surfaces of the substrates 20 and 21.

As illustrated in FIGS. 1 and 2, the opposed substrate 20 has a short-side dimension that is smaller than a short-side dimension of the array substrate 21. The opposed substrate 20 is bonded to the array substrate 21 such that one of the long sides of the opposed substrate 20 is aligned with a corresponding one of the long sides of the array substrate 21. Therefore, a long side edge section including another one of the long sides of the array substrate 21 projects from another one of the long sides of the opposed substrate 20 and a projecting long side edge section is an uncovered section 21A. An entire area of the uncovered section 21A is the non-display area NAA and drivers 12 (a signal supply section) that are components for supplying various signals related to the display function and the touch panel function and a flexible substrate 13 are mounted on the uncovered section 21A.

The drivers 12 illustrated in FIGS. 1 and 2 are LSI chips including driver circuits therein. The drivers 12 are mounted on the uncovered section 21A of the array substrate 21 through the chip-on-glass (COG) technology. The driver 12 processes the various kinds of signals transmitted from the flexible substrate 13. The drivers 12 supply various kinds of signals (such as image signals and touch signals) to the lines (source lines 27 and touch lines 30 which will be described later) on the display area AA. The flexible substrate 13 includes a substrate made of synthetic resin (e.g., polyimide-based resin) having insulating property and flexibility and multiple traces formed on the substrate. As illustrated in FIGS. 1 and 2, a first end of the flexible substrate 13 is connected to the uncovered section 21A of the array substrate 21 and a second end of the flexible substrate 13 is connected to a circuit board (such as a control board). The flexible substrate 13 is connected to an end of the uncovered section 21A that is an opposite end from the display area AA with respect to the drivers 12 in the Y-axis direction.

The liquid crystal panel 11 according to this embodiment has a display function for displaying images and a touch panel function for detecting positions of input performed by a user based on the displayed images (input positions). The liquid crystal panel 11 includes an integrated touch panel pattern (with an in-cell technology) for exerting the touch panel function. The touch panel pattern uses so-called a projection type electrostatic capacitance method. A self-capacitance method is used for detection. As illustrated in FIG. 1, the touch panel pattern includes touch electrodes 29 (a position detection electrode) that are arranged in a matrix within a plate surface of the liquid crystal panel 11. The touch electrodes 29 are disposed in the display area AA of the liquid crystal panel 11. The display area AA of the liquid crystal panel 11 substantially corresponds to a touch area in which input positions are detectable (a position input area). The non-display area NAA substantially corresponds to a non-touch area in which input positions are not detectable (a non-position input area). When the user intends to input a position based on a displayed image that is displayed in the display area AA of the liquid crystal panel 11 and the user moves a finger (a position input body) that is an electrically conductive member closer to the surface of the liquid crystal panel 11, the finger and the touch electrode 29 form a capacitor. A capacitance measured at the touch electrode 29 close to the finger changes as the finger approaches the touch electrode 29 and is different from a capacitance at the touch electrodes 29 farther from the finger. Based on the difference in capacitance, the input position can be detected. The number of the touch electrodes 29 may be altered as appropriate from that illustrated in FIG. 1. The touch electrode 29 has a substantially square plan view shape and one side dimension is about several millimeters. The plan view size of the touch electrode 29 is much larger than that of a pixel, which will be described later. The touch electrode 29 extends to overlap the pixels both in the X-axis direction and the Y-axis direction.

As illustrated in FIG. 1, touch lines 30 (position detection lines), that are included in the liquid crystal panel 11, are selectively connected to the touch electrodes 29, respectively. The touch lines 30 extend substantially along the Y-axis direction. A first end of the touch line 30 is connected to the driver 12 in the non-display area NAA and a second end of the touch line 30 is connected to a particular one of the touch electrodes 29 that are arranged along the Y-axis direction in the display area AA. The touch lines 30 are connected to a detection circuit. The detection circuit may be included in the driver 12 but may be disposed outside the liquid crystal panel 11 via the flexible substrate 13. A detailed configuration of the touch lines 30 will be described later.

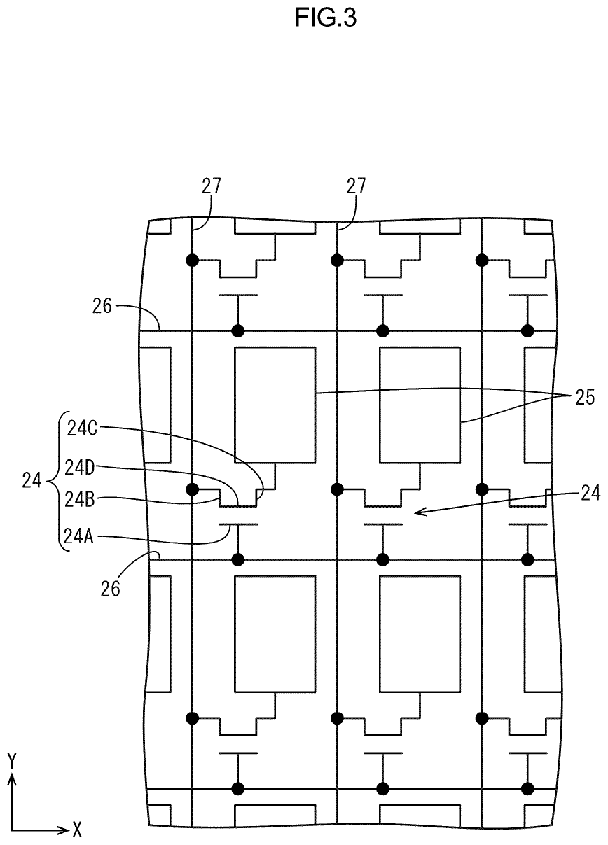

Next, a configuration of the array substrate 21 in the display area AA will be described with reference to FIG. 3. As illustrated in FIG. 3, at least TFTs 24 (switching components) and pixel electrodes 25 are arranged on an inner surface of the array substrate 21 in the display area AA. The TFTs 24 and the pixel electrodes 25 are arranged at intervals in a matrix (rows and columns) along the X-axis direction and the Y-axis direction. Gate lines 26 (third lines, scanning lines) and source lines 27 (image lines, signal lines) are routed perpendicular to each other to surround the TFTs 24 and the pixel electrodes 25. The gate lines 26 extend along the X-axis direction and are arranged at intervals with respect to the Y-axis direction. The source lines 27 extend along the Y-axis direction (a first direction) and are arranged at intervals with respect to the X-axis direction (a second direction crossing the first direction). The TFT 24 includes a gate electrode 24A (a first electrode) connected to the gate line 26, a source electrode 24B (a second electrode) connected to the source line 27, a drain electrode 24C (a third electrode) connected to the pixel electrode 25, and a semiconductor section 24D connected to the source electrode 24B and the drain electrode 24C. The TFTs 24 are driven based on scan signals supplied to the gate electrodes 24A through the gate lines 26. The scan signals include a potential higher than the threshold voltage of the TFTs 24. The potential of the image signal (a signal) supplied to the source electrode 24B through the source line 27 from the driver 12 is supplied to the drain electrode 24C via the semiconductor section 24D. As a result, the pixel electrode 25 is charged at the potential of the image signal. The pixel electrode 25 is disposed in an area surrounded by the gate lines 26 and the source lines 27 and has a rectangular plan view shape.

Color filters are disposed in the display area AA of the opposed substrate 20 to be opposed to the pixel electrodes 25 on the array substrate 21 side. The color filters that exhibit three different colors of red (R), green (G), blue (B) are arranged repeatedly in a predefined order. The color filter and the corresponding pixel electrode 25 are configured as a pixel of each color (a red pixel, a green pixel, and a blue pixel). The three pixels of the red pixel, the green pixel, and the blue pixel are configured as a display pixel that can exert color display with a predetermined gradation. A light blocking portion (a black matrix) is disposed between the color filters to prevent mixing of colors. Alignment films for orienting the liquid crystal molecules in the liquid crystal layer 22 are formed on innermost surfaces (in an uppermost layer) of the substrates 20 and 21 in contact with the liquid crystal layer 22.

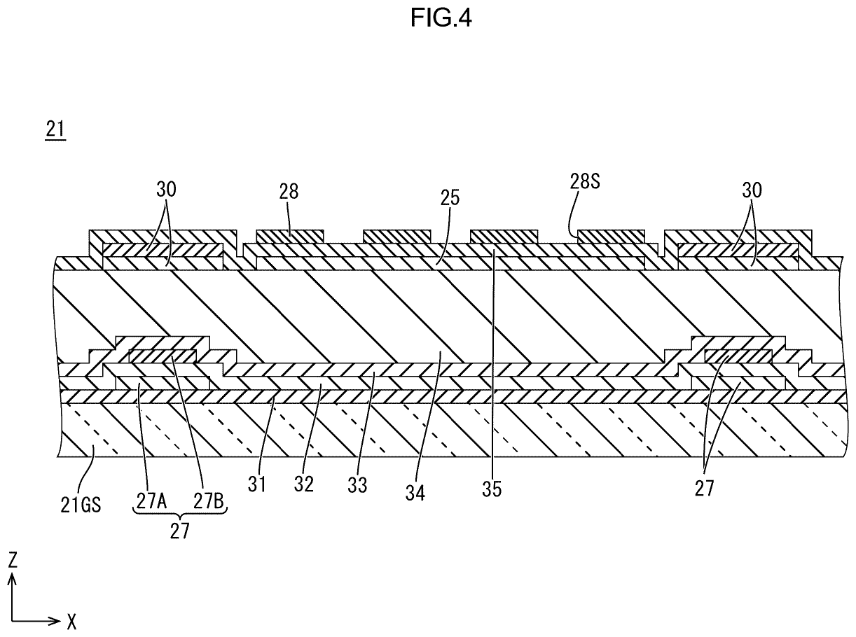

Next, a cross-sectional configuration of the pixel electrodes 25 in a middle section of the array substrate 21 will be described with reference to FIG. 4. As illustrated in FIG. 4, a common electrode 28 is formed on an inner surface side of the array substrate 21 in the display area AA to overlap all the pixel electrodes 25. The common electrode 28 spreads in a substantially entire area of the display area AA. The common electrode 28 includes slits 28S in a portion overlapping the pixel electrode 25. The common electrode 28 is disposed on an upper layer side (the liquid crystal layer 22 side) of the pixel electrode 25 via a third interlayer insulating film 35. The common electrode 28 is supplied with a common potential signal of a common potential (a reference potential). With the pixel electrode 25 being charged at a potential based on the image signal supplied to the source line 27 according to the driving of the TFT 24, a potential difference occurs between the pixel electrode 25 and the common electrode 28. Then, a fringe electric field (an oblique electric field) is created between an opening edge of a the slit 28S of the common electrode 28 and the pixel electrode 25. The fringe electric field includes a component parallel to the plate surface of the array substrate 21 and a component normal to the plate surface of the array substrate 21. With the fringe electric field, orientations of the liquid crystal molecules included in the liquid crystal layer 22 can be controlled and predefined displaying is performed based on the orientations of the liquid crystal molecules. Namely, the liquid crystal panel 11 according to this embodiment operates in the fringe field switching (FFS) mode.

As illustrated in FIG. 1, the touch electrodes 29 are portions of the common electrode 28. The common electrode 28 includes dividing openings 28A (dividing slits) for separating the adjacent touch electrodes 29 from each other. The dividing openings 28A include first dividing openings 28A1 that cross the common electrode 28 in the X-axis direction for an entire length of the common electrode 28 and second dividing openings 28A2 that cross the common electrode 28 in the Y-axis direction for an entire length of the common electrode 28. The dividing openings 28A are formed in a grid in a plan view as a whole. The common electrode 28 is divided into the touch electrodes 29 with a grid pattern in a plan view by the dividing openings 28A and includes the touch electrodes 29 that are electrically independent from one another. The touch electrodes 29 that are arranged along the Y-axis direction are separated by the first dividing openings 28A1 and the touch electrodes 29 that are arranged along the X-axis direction are separated by the second dividing openings 28A2. The touch lines 30 that are connected to the touch electrodes 29 are supplied with common potential signals for the image display function and touch signals (a position detection signal) for the touch panel function from the driver 12 at different timings. A period while the touch lines 30 are supplied with the common potential signals from the driver 12 is a display period and a period while the touch lines 30 are supplied with the touch signals from the driver 12 is a sensing period (a position detection period). The common potential signals are transmitted to all the touch lines 30 at the same timing (for the display period) and thus all the touch electrodes 29 are charged at the reference potential based on the common potential signals and function as the common electrode 28.

As illustrated in FIGS. 4 and 5, the touch lines 30 are disposed to overlap the source lines 27, respectively, in a plan view. As illustrated in FIG. 1, the touch lines 30 cross the first dividing openings 28A1 that define each of the touch electrodes 29 that are adjacent to each other in the Y-axis direction.

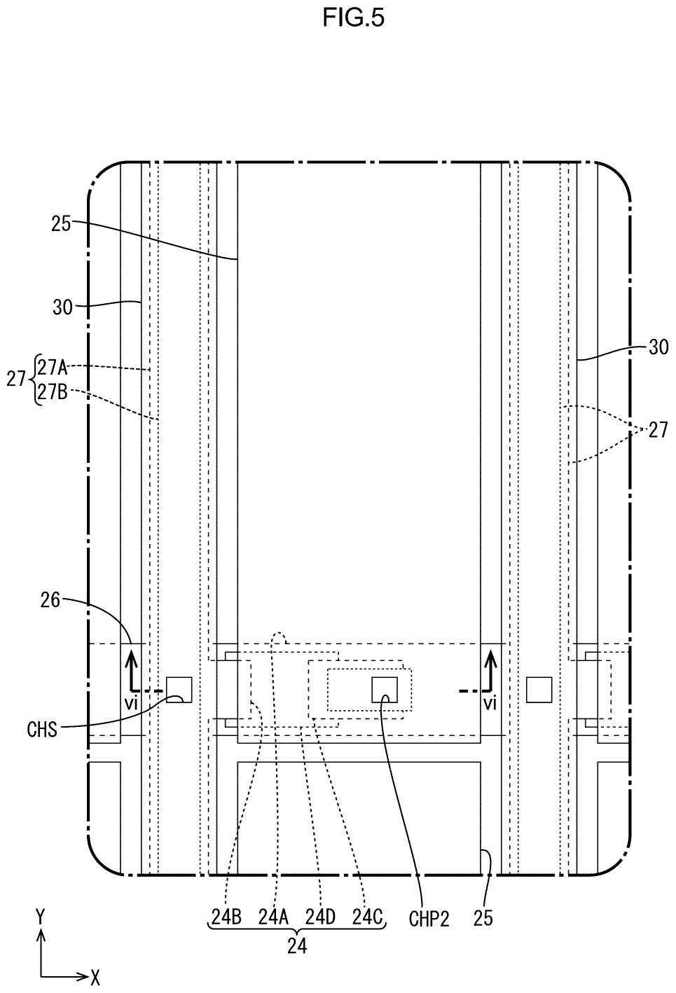

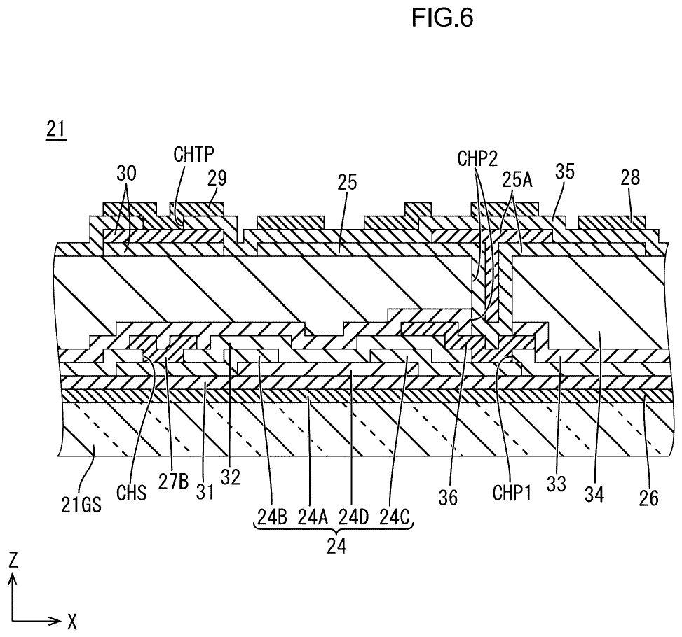

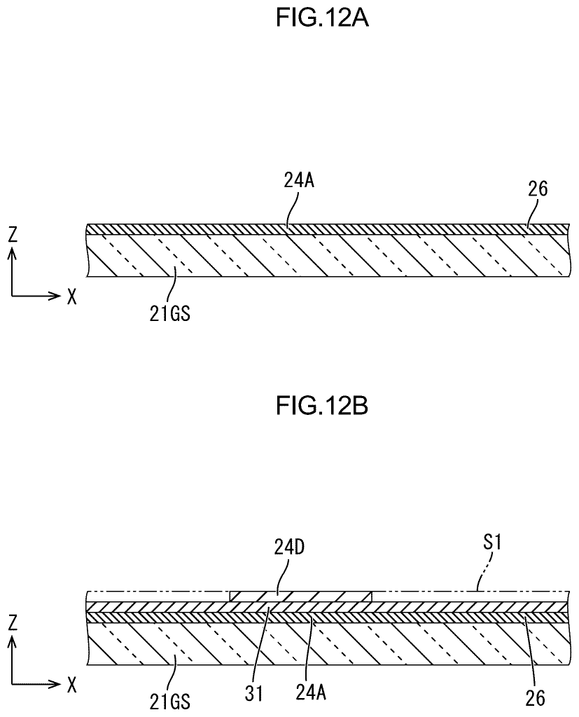

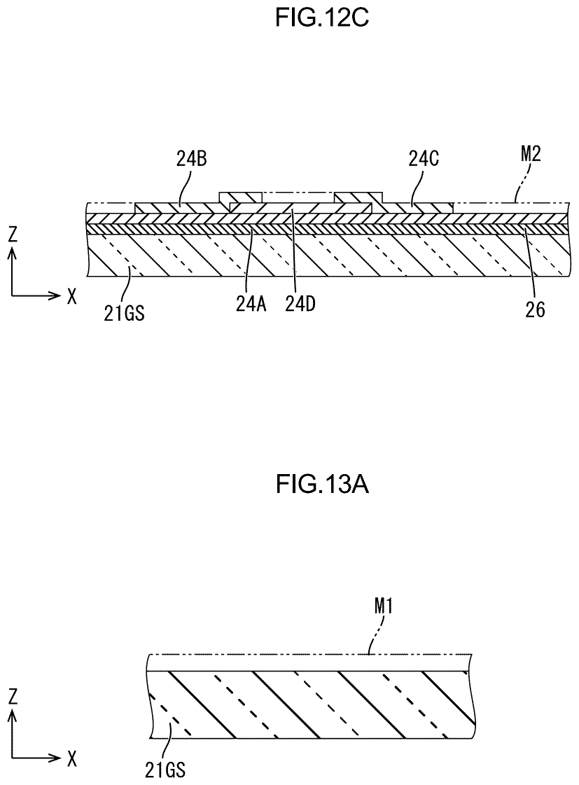

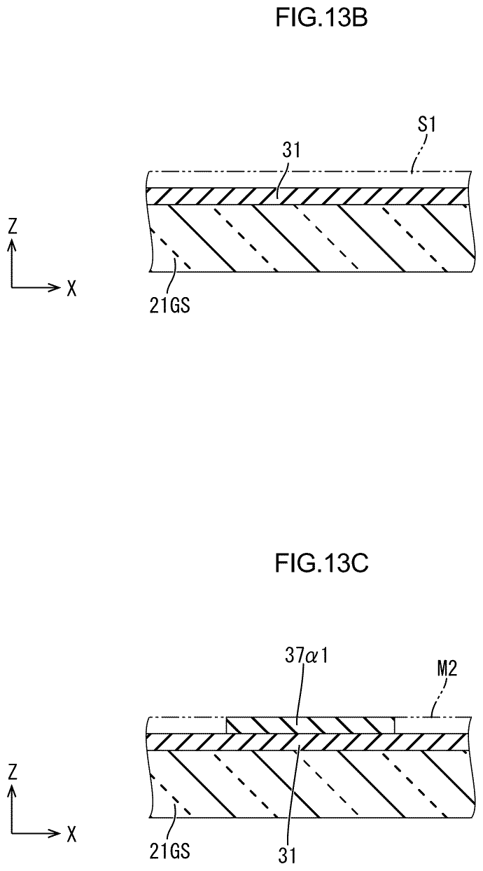

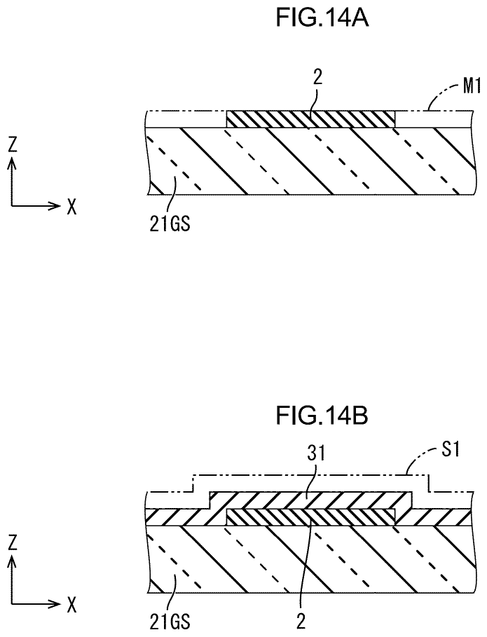

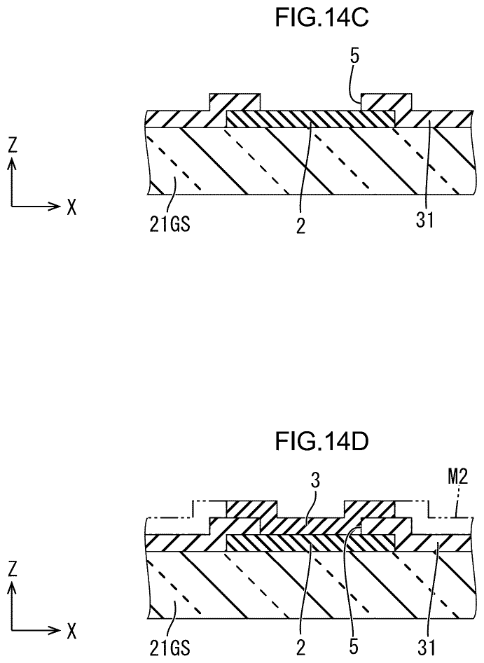

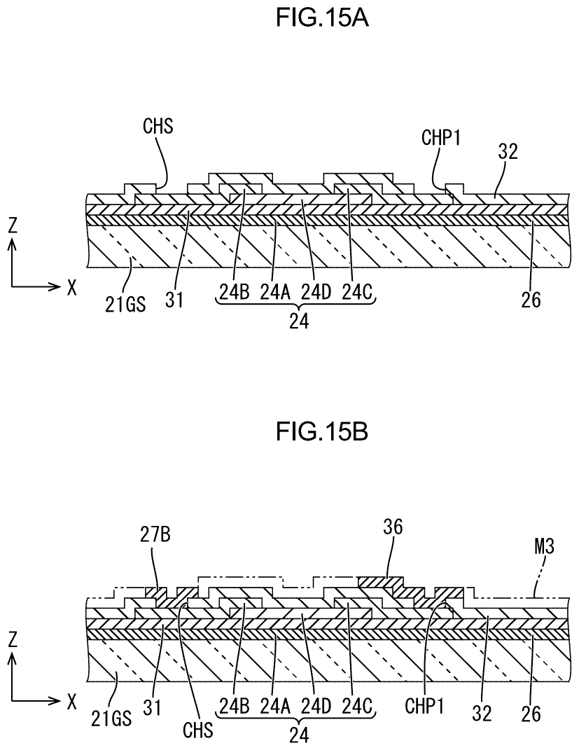

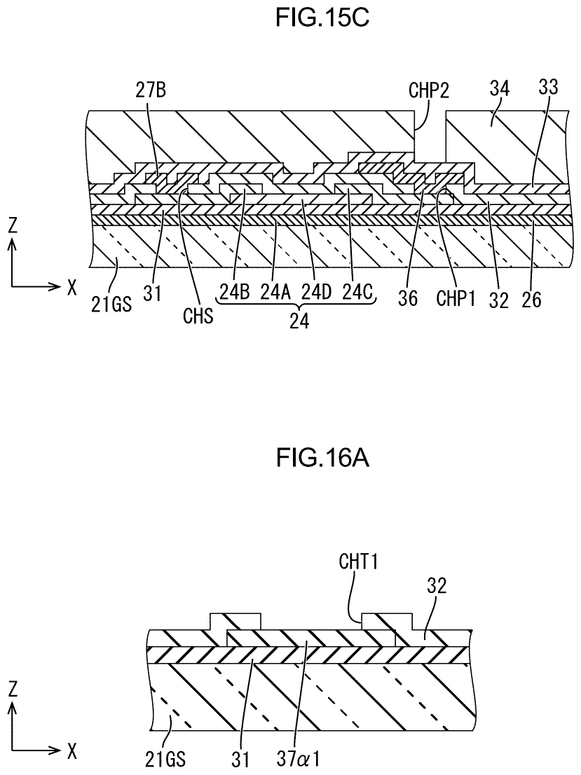

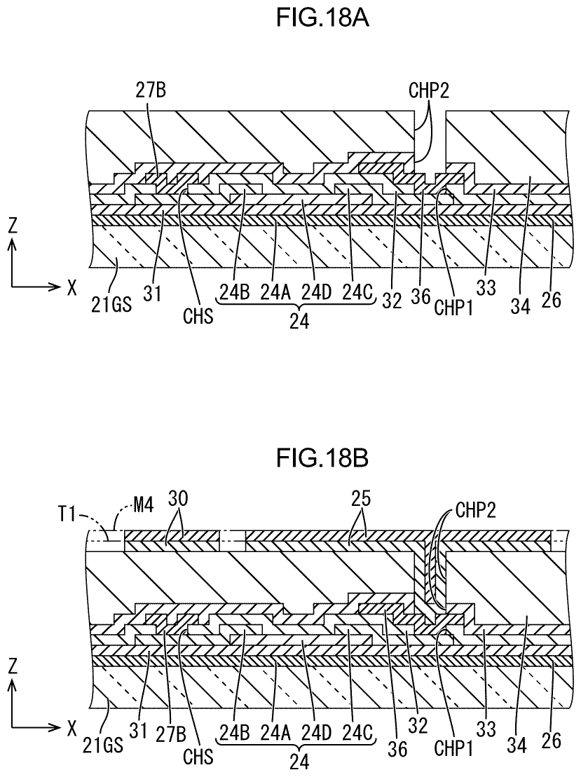

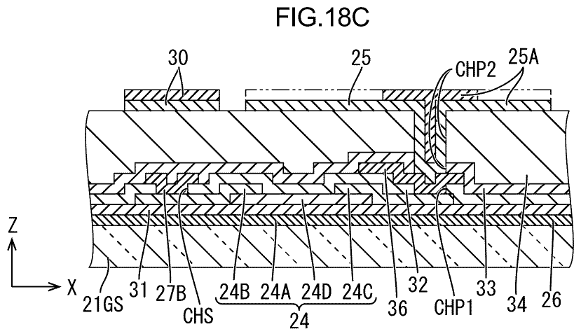

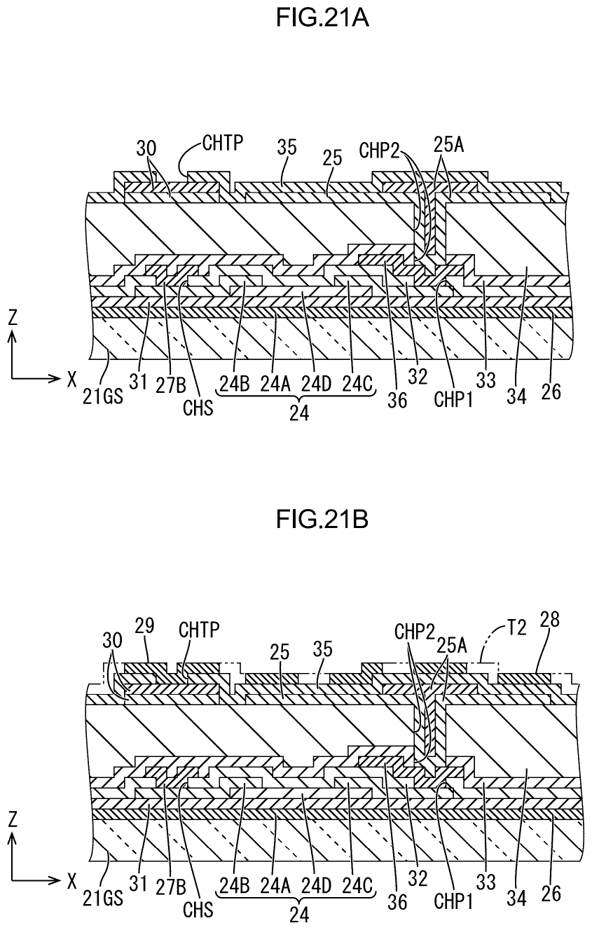

Films disposed on top of each other on the inner surface side of the array substrate 21 will be described with reference to FIG. 6. FIG. 6 illustrates a cross-sectional configuration of a portion of the array substrate 21 near the TFT 24. As illustrated in FIG. 6, on the glass substrate 21GS (a substrate) of the array substrate 21, a first metal film M1 (a first conductive film), a gate insulating film 31 (a first insulating film), a semiconductor film S1, a second metal film M2 (a second conductive film), a first interlayer insulating film 32 (a second insulating film), a third metal film M3 (a third conductive film), a second interlayer insulating film 33 (a third insulating film), a planarizing film 34 (a third insulating film), a first transparent electrode film T1 (a fourth conductive film), a fourth metal film M4 (a fourth conductive film), a third interlayer insulating film 35 (a fourth insulating film), a second transparent electrode film T2 (a fifth conductive film), and an alignment film are disposed on top of each other in this sequence from a lower layer side (from the glass substrate 21GS side). Among the films, the first metal film M1 is illustrated in FIGS. 13A and 14A, the semiconductor film S1 is illustrated in FIGS. 12B, 13B, and 14B, the second metal film M2 is illustrated in FIGS. 12C, 13C, and 14D, the third metal film M3 is illustrated in FIGS. 15B, 16B, and 17B, the first transparent electrode film T1 and the fourth metal film M4 are illustrated in FIGS. 18B, 19B, and 20B, and the second transparent electrode film T2 is illustrated in FIGS. 21B, 22B, and 23B.

The first metal film M1, the second metal film M2, the third metal film M3, and the fourth metal film M4 may be a single-layer film made of one kind of metal, a multilayer film made of a material containing different kinds of metals, or an alloy. Examples of the metals include copper, titanium, aluminum, molybdenum, and tungsten. With such a configuration, the first metal film M1, the second metal film M2, the third metal film M3, and the fourth metal film M4 have electrically conductive properties and light blocking properties. Portions of the first metal film M1 are configured as the gate lines 26 and the gate electrodes 24A of the TFTs 24. Portions of the second metal film M2 are configured as portions of the source lines 27 and source electrodes 24B and the drain electrodes 24C of the TFTs 24. Portions of the third metal film M3 are configured as portions of the source lines 27. Portions of the fourth metal film M4 are configured as portions of the touch lines 30 and portions of the pixel electrodes 25. The first transparent electrode film T1 and the second transparent electrode film T2 are made of a transparent electrode material (e.g., indium tin oxide (ITO) and indium zinc oxide (IZO)). Portions of the first transparent electrode film T1 are configured as portions of the touch lines 30 and portions of the pixel electrodes 25. A portion of the second transparent electrode film T2 is configured as the common electrode 28 (the touch electrodes 29). Arrangement of the alignment films is as previously described.

The semiconductor film S1 is made of an oxide semiconductor material and portions of the semiconductor film S1 are configured as the semiconductor sections 24D of the TFTs 24. The semiconductor film S1 may include at least one kind of metallic elements out of In, Ga, and Zn and may be an In—Ga—Zn—O semiconductor (for example, In—Ga—Zn oxide). The In—Ga—Zn—O semiconductor is ternary oxide of indium (In), gallium (Ga), and zinc (Zn). A ratio (composition ratio) of indium (In), gallium (Ga), and zinc (Zn) is not particularly limited and may be In:Ga:Zn=2:2:1, In:Ga:Zn=1:1:1, and In:Ga:Zn=1:1:2, for example. The In—Ga—Zn—O semiconductor used for the semiconductor film S1 may be amorphous or may be crystalline. The semiconductor film S1 may include other oxide semiconductor instead of the In—Ga—Zn—O semiconductor. For example, the semiconductor film S1 may include an In—Sn—Zn—O semiconductor (for example, In₂O₃—SnO₂—ZnO; InSnZnO). The In—Sn—Zn—O semiconductor is ternary oxide of indium (In), tin (Sn), and zinc (Zn). The oxide semiconductor layer may include an In—W—Zn—O semiconductor, an In—W—Sn—Zn—O semiconductor that include tungsten (W), an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, an In—Ga—Sn—O semiconductor, an In—Ga—O semiconductor, a Zr—In—Zn—O semiconductor, a Hf—In—Zn—O semiconductor, an Al—Ga—Zn—O semiconductor, a Ga—Zn—O semiconductor, and an In—Ga—Zn—Sn—O semiconductor. The resistance value of the oxide semiconductor material of the semiconductor film S1 with no application of a voltage (off state) is higher than that of polysilicon semiconductor material. The oxide semiconductor material of the semiconductor film S1 has electron mobility higher than that of amorphous silicon semiconductor material.

The gate insulating film 31, the first interlayer insulating film 32, the second interlayer insulating film 33, and the third interlayer insulating film 35 are made of an inorganic material such as silicon nitride (SiNₓ) and silicon oxide (SiO₂). The thickness of each of the gate insulating film 31, the first interlayer insulating film 32, the second interlayer insulating film 33, and the third interlayer insulating film 35 is greater than a thickness of the first transparent electrode film T1 and a thickness of the second transparent electrode film T2. Among the films, the first interlayer insulating film 32 that is included in a layer upper than the semiconductor film S1 includes silicon oxide as an inorganic material and is thicker than the gate insulating film 31, the second interlayer insulating film 33, and the third interlayer insulating 35, which other inorganic film are insulating films. With the first interlayer insulating film 32 having such a configuration, impurities (moisture, for instance) are less likely to be dispersed from the layers (the planarizing film 34, for instance) upper than the first interlayer insulating film 32 to the semiconductor film S1. Therefore, operation reliability of the TFTs 24 including the semiconductor sections 24D, which are portions of the semiconductor film S1, is increased and manufacturing yield of the array substrate 21 is improved. The planarizing film 34 is an organic insulating film made of an organic material such as PMMA (acrylic resin). The planarizing film 34 is much thicker than the gate insulating film 31, the first interlayer insulating film 32, the second interlayer insulating film 33, and the third interlayer insulating film 35. The planarizing film 34 planarizes the inner surface (a surface opposite the liquid crystal layer 22) of the array substrate 21.

A configuration of the TFTs 24 will be described in detail. As illustrated in FIGS. 5 and 6, in the TFTs 24, the gate electrodes 24A, which are portions of the first metal film M1, are disposed in a layer lower than (below) the semiconductor sections 24D, which are portions of the semiconductor film S1, via the gate insulating film 31. Namely, the TFTs 24 are bottom-gate type transistors. The gate electrodes 24A are portions of the gate lines 26 (portions overlapping the semiconductor sections 24D) that extend in the X-axis direction. The source electrode 24B and the drain electrode 24C, which are portions of the second metal film M2, are disposed at an interval with respect to the X-axis direction. Portions of the source electrode 24B and the drain electrode 24C are above and directly contacted with the semiconductor section 24D. The source electrodes 24B are protrusion sections of the source lines 27. Specifically, the source line 27 has a wide section in a portion crossing the gate line 26 and the wide section is configured as the source electrode 24B. Intermediate electrodes 36 (a fourth electrode), which are portions of the third metal film M3, are disposed to overlap end portions of the drain electrodes 24C opposite from the end portions overlapping the semiconductor sections 24D, respectively. The first interlayer insulating film 32, which is disposed between the drain electrodes 24C and the intermediate electrodes 36, include first pixel contact holes CHP1 (a third contact hole). The drain electrodes 24C are connected to the intermediate electrodes 36, respectively, via the first pixel contact holes CHP1. The intermediate electrodes 36 are disposed to overlap portions of the pixel electrodes 25. The second interlayer insulating film 33 and the planarizing film 34, which are disposed between the intermediate electrodes 36 and the portions of the pixel electrode 25, include second pixel contact holes CHP2 (a fourth contact hole) such that the second pixel contact hole CHP2 in the second interlayer insulating film 33 and that in the planarizing film 34 communicate with each other. The intermediate electrodes 36 are connected to the pixel electrodes 25, respectively, via the second pixel contact holes CHP2.

As illustrated in FIGS. 4 and 6, the pixel electrode 25 has an overlapping portion that overlaps the intermediate electrode 36 and a non-overlapping portion that does not overlap the intermediate electrode 36. The overlapping portion has a multilayer structure including the first transparent electrode film T1 and the third metal film M3. The non-overlapping portion has a single layer structure of the first transparent electrode film T1 and does not include the third metal film M3. The overlapping portion of the pixel electrode 25 that overlaps the intermediate electrode 36 includes the third metal film M3 and functions as a light blocking portion 25A that blocks light. The light blocking portion 25A is disposed to overlap the pixel contact holes CHP1, CHP2. Therefore, even if orientation errors occur in the liquid crystal molecules and light leaks from the portion adjacent to the pixel contact holes CHP1, CHP2 due to the pixel contact holes CHP1, CHP2, the leaking light can be blocked by the light blocking portion 25A. On the other hand, the touch lines 30 have a multilayer structure including the first transparent electrode film T1 and the third metal film M3 over an entire length thereof. The portion of the pixel electrode 25 other than the light blocking portion 25A has a single layer structure of the first transparent electrode film T1 and does not include the third metal film M3. Therefore, the portion of the pixel electrode 25 other than the light blocking portion 25A effectively transmits light from the backlight unit.

A configuration of the source line 27 will be described. As illustrated in FIGS. 4 to 6, the source line 27 includes a lower layer line 27A (a second line) that is a portion of the second metal film M2 and an upper layer line 27B (a first line) that is a portion of the third metal film M3. The lower layer line 27A and the upper layer line 27B extend along the Y-axis direction and overlap in most areas thereof via the first interlayer insulating film 32. The lower layer line 27A and the upper layer line 27B are disposed such that center lines with respect to the width direction (the X-axis direction) match. The lower layer line 27A, which is a portion of the second metal film M2, has a wide section in a portion thereof crossing the gate line 26 and the wide section is configured as the source electrode 24B. The upper layer line 27B, which is a portion of the third metal film M3, has a substantially constant width over an entire length. The upper layer line 27B is narrower than the lower layer line 27A except for the source electrode 24B. The upper layer line 27B overlaps the lower layer line 27A with a substantially entire length. Therefore, a portion of the upper layer line 27B overlaps the source electrode 24B that is a portion of the lower layer line 27A. The first interlayer insulating film 32, which is disposed between the second metal film M2 and the third metal film M3, includes a source contact hole CHS (a first contact hole) in a portion that overlaps the lower layer line 27A and the upper layer line 27B. The source electrode 24B and the upper layer line 27B are connected via the source contact hole CHS in the first interlayer insulating film 32. The lower layer line 27A is connected to the upper layer line 27B via the source electrode 24B. The number of source contact holes CHS that overlap the upper layer lines 27B is same as the number of TFTs 24 arranged along the Y-axis direction (the number of gate lines 26). The source line 27 includes the lower layer line 27A and the upper layer line 27B that are connected to each other. With such a configuration, the resistance of the source line 27 can be reduced compared to a configuration in which the source line includes only one of the lower layer line 27A and the upper layer line 27B. Furthermore, if one of the lower layer line 27A and the upper layer line 27B is disconnected, the signals can be transferred via the other one and redundancy can be achieved. Most portions of the lower layer line 27A and the upper layer line 27B overlap via the first interlayer insulating film 32. Therefore, the lower layer line 27A and the upper layer line 27B can be disposed in a small space in the display area AA and the aperture ratio of the pixels can be preferably increased.

A connection structure of the touch electrodes 29 (the common electrode 28) and the touch lines 30 will be described. As illustrated in FIG. 6, the third interlayer insulating film 35 is disposed between the touch line 30, which is a portion of the third metal film M3, and the touch electrode 29, which is a portion of the second transparent electrode film T2. The third interlayer insulating film 35 includes touch contact holes CHTP via which the touch lines 30 and the touch electrodes 29 are connected. The touch contact hole CHTP is in a portion of the third interlayer insulating film 35 that overlaps the touch line 30 and the target touch electrode 29 that is to be connected to the touch line 30.

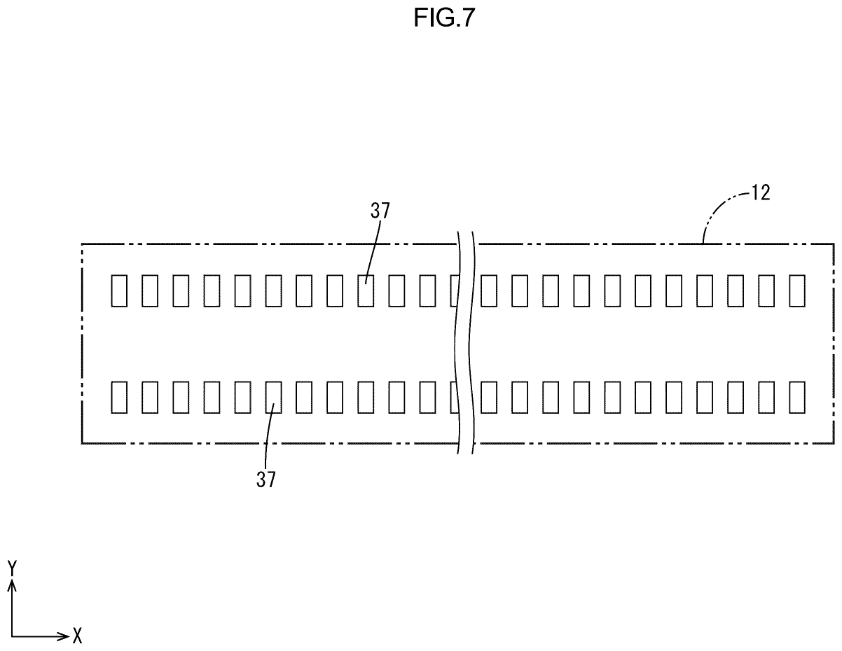

As illustrated in FIG. 7, terminals 37 are disposed on an inner surface of the uncovered section 21A that is the non-display area NAA of the array substrate 21. The terminals 37 are disposed at least in a driver arrangement area of the uncovered section 21A where the driver 12 is disposed (a mount area) and the driver arrangement area overlaps the driver 12 in a plan view. In FIG. 7, the driver arrangement area in which the driver 12 is arranged is illustrated with a double-dashed dotted line and the terminals 37 are disposed in the driver arrangement area. The terminals 37 are also disposed in a flexible substrate arrangement area of the uncovered section 21A where the flexible substrate 13 is arranged (the mount area) and the flexible substrate arrangement area overlaps the flexible substrate 13 in a plan view (refer to FIGS. 1 and 2). The terminals 37 disposed in the driver arrangement area are connected to the lines extending from the source lines 27 disposed in the display area AA and the lines extending from the circuit portions 14 and the lines extending from the flexible substrate arrangement area. The terminals 37 disposed in the flexible substrate arrangement area are connected to the lines extending from the circuit portions 14 and the lines extending from the driver arrangement area. The terminals 37 disposed in the driver arrangement area include output terminals for outputting signals to the drivers 12 and input terminals for receiving the signals from the drivers 12. A detailed configuration of the terminals 37 will be described later.

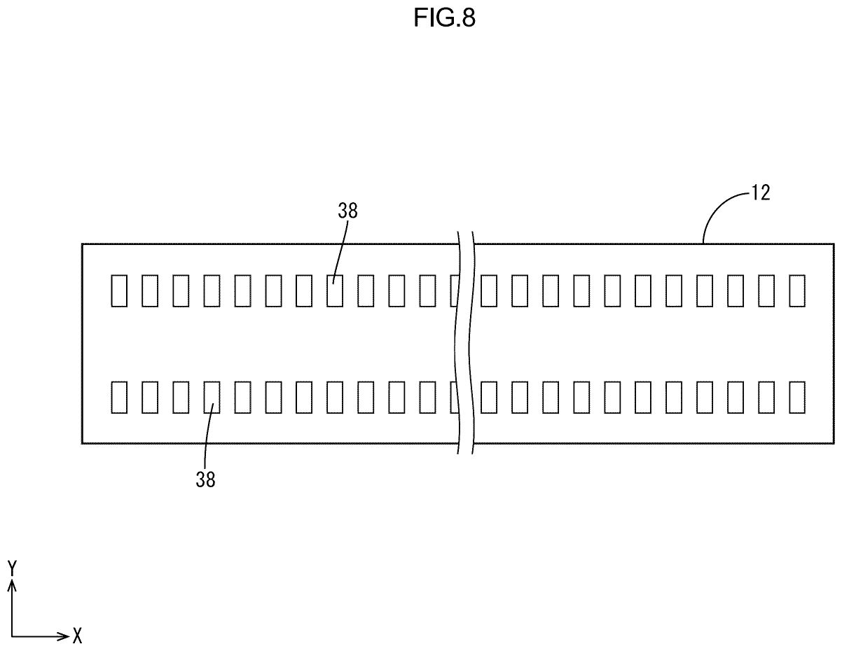

As illustrated in FIG. 8, bumps 38 are disposed on a surface (a bottom surface, a rear surface) of the driver 12 that is opposite the array substrate 21. The terminals 37 are connected to the bumps 38, respectively. The bumps 38 protrude in the Z-axis direction from the surface of the driver 12 toward the array substrate 21. The bumps 38 are connected to a circuit included in the driver 12. The bumps 38 are arranged in a portion of the surface of the driver 12 so as to overlap the respective terminals 37 on the array substrate 21. The bumps 38 include input bumps that receives signals from the array substrate 21 and output bumps from which the signals are output to the array substrate 21.

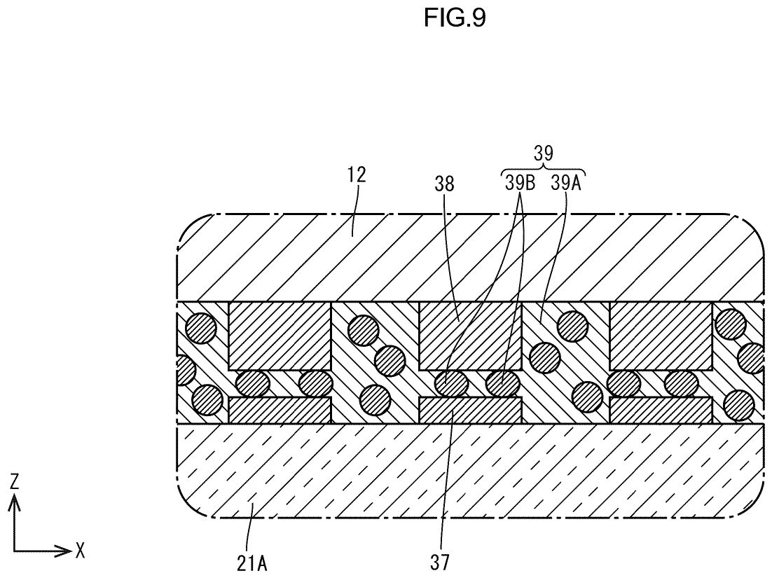

As illustrated in FIG. 9, the terminals 37 disposed in the driver arrangement area of the array substrate 21 and the bumps 38 of the driver 12 are connected to each other via an anisotropic conductive film (ACF) 39. The anisotropic conductive film 39 will be described. The anisotropic conductive film 39 includes a binder 39A made of thermosetting resin material and conductive particles 39B dispersed in the binder 39A. In mounting the driver 12, the anisotropic conductive film 39 and the driver 12 are placed on the driver arrangement area of the array substrate 21 and the driver 12 is thermally pressed toward the array substrate 21. Then, the terminals 37 on the array substrate 21 and the bumps 38 on the driver 12 are electrically connected via the conductive particles 39B. With the binder 39A being thermally cured, the driver 12 is mechanically fixed to the array substrate 21. The terminals 37 disposed in the flexible substrate arrangement area of the array substrate 21 are connected to terminals on the flexible substrate 13 with using the anisotropic conductive film 39 similar to that previously described.

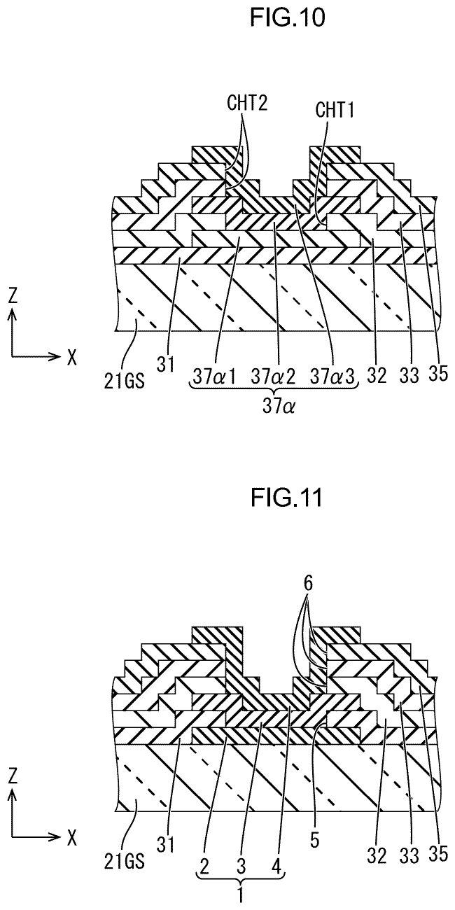

The terminals 37 include a first terminal 37α illustrated in FIG. 10. The first terminal 37α at least includes a second metal film portion 37α1 (a first terminal portion) that is a portion of the second metal film M2 and a third metal film portion 37α2 (a second terminal portion) that is a portion of the third metal film M3. On the array substrate 21, at least the uncovered section 21A (including the driver arrangement area and the flexible substrate arrangement area) does not include the planarizing film 34. The planarizing film 34 is removed from an almost entire area of the uncovered section 21A. The second metal film portion 37α1 is disposed above the gate insulation film 31. The third metal film portion 37α2 is disposed to overlap the second metal film portion 37α1 via the first interlayer insulating film 32. The first interlayer insulating film 32, which is disposed between the second metal film portion 37α1 and the third metal film portion 37α2, includes a first terminal contact hole CHT1 (a second contact hole) in a portion overlapping the second metal film portion 37α1 and the third metal film portion 37α2. The second metal film portion 37α1 and the third metal film portion 372 are connected via the first terminal contact hole CHT1 in the first interlayer insulating film 32.

As illustrated in FIG. 10, the first terminal 37α includes a transparent electrode portion 37α3, which is a portion of the second transparent electrode film T2, in addition to the second metal film portion 37α1 and the third metal film portion 37α2. The transparent electrode portion 37α3 is disposed to overlap the third metal film portion 37α2 via the second interlayer insulating film 33 and the third interlayer insulating film 35. The second interlayer insulating film 33 and the third interlayer insulating film 35, which are disposed between the third metal film portion 37α2 and the transparent electrode portion 37α3, include second terminal contact holes CHT2 in portions overlapping both of the third metal film portion 37α2 and the transparent electrode portion 37α3. The corresponding second terminal contact holes CHT2 in the second interlayer insulating film 33 and the third interlayer insulating film 35 communicate each other. The third metal film portion 37α2 and the transparent electrode portion 37α3 are connected via the second terminal contact holes CHT2 in the second interlayer insulating film 33 and the third interlayer insulating film 35. Thus, the second metal film portion 37α1 and the third metal film portion 37α2, which are made of metal material, are covered and protected by the transparent electrode portion 37α3, which is made of transparent electrode material, and are less likely to be corroded.

If the terminals 37 include a terminal 1 having a configuration illustrated in FIG. 11, problems described below may be caused. The configuration of the terminal 1 and the problems will be described. The terminal 1 includes a first metal film portion 2, which is a portion of the first metal film M1, a second metal film portion 3, which is a portion of the second metal film M2, and a transparent electrode portion 4, which is a portion of the second transparent electrode film T2. The first metal film portion 2, the second metal film portion 3, and the transparent electrode portion 4 are connected to each other. The gate insulating film 31, which is disposed between the first metal film portion 2 and the second metal film portion 3, includes a contact hole 5 for connecting the first metal film portion 2 and the second metal film portion 3. The first interlayer insulating film 32, the second interlayer insulating film 33, and the third interlayer insulating film 35, which are disposed between the second metal film portion 3 and the transparent electrode portion 4, include contact holes 6 for connecting the second metal film portion 3 and the transparent electrode portion 4. In the process of producing the terminal 1 having such a configuration, after forming the third interlayer insulating film 35, the contact holes 6 need to be formed in the first interlayer insulating film 32, the second interlayer insulating film 33, and the third interlayer insulating film 35 so as to be communicated with each other. On the other hand, in the display area AA, after forming the first interlayer insulating film 32, the source contact hole CHS and the first pixel contact hole CHP1 are formed in the first interlayer insulating film 32. Therefore, with the terminals 37 including the terminal 1, the number of times the first interlayer insulating film 32 is processed is increased and the time necessary for processing becomes longer. Particularly, in this embodiment, the first interlayer insulating film 32 is thicker than other inorganic insulating films (the gate insulating film 31, the second interlayer insulating film 33, and the third interlayer insulating film 35), and therefore the problems tend to be obvious. With the terminal 37 including three or more layers of metal films, an indentation created on the surface of the terminal 37 when the driver 12 is mounted is hardly recognized during a test. Therefore, the number of metal films included in the terminal 37 is necessarily two layers or less.

In this respect, according to this embodiment, in the non-display area NAA, the first terminal 37α included in the terminals 37 includes the second metal film portion 37α1, which is a portion of the second metal film M2, and the third metal film portion 37α2, which is a portion of the third metal film M3, and the second metal film portion 37α1 and the third metal film portion 37α2 are connected via the first terminal contact hole CHT1 in the first interlayer insulating film 32, as illustrated in FIG. 10. In the display area AA, as illustrated in FIG. 6, the source electrode 24B, which is a portion of the second metal film M2, and the upper layer line 27B, which is a portion of the third metal film M3, are connected via the source contact hole CHS in the first interlayer insulating film 32. Therefore, in the producing process, after forming the first interlayer insulating film 32, the source contact hole CHS and the first terminal contact hole CHT1 can be formed in the first interlayer insulating film 32 in the same process step. Accordingly, the number of times the first interlayer insulating film 32 is processed is reduced compared to the configuration in which the terminals 37 include the terminal 1.

The first terminals 37α having the above configuration are connected to the lines extending from the source lines 27 and the circuit portion 14 (hereinafter referred to as an extending line) as described below. With the extending line being a portion of the second metal film M2, for instance, the extending line is directly continuous to the second metal film portion 37α1. With the extending line being a portion of the third metal film M3, for instance, the extending line is directly continuous to the third metal film portion 37α2. With the extending line being a portion of the first metal film M1, for instance, the extending line is connected to the second metal film portion 37α1 via the contact hole formed in the gate insulating film 31. With the extending line being a portion of the first transparent electrode film T1 and a portion of the fourth metal film M4, for instance, the extending line is connected to the third metal film portion 37α2 via the contact hole formed in the second interlayer insulating film 33.

Furthermore, according to this embodiment, in the display area AA, the drain electrode 24C, which is a portion of the second metal film M2, and the intermediate electrode 36, which is a portion of the third metal film M3, are connected via the first pixel contact hole CHP1 in the first interlayer insulating film 32 as illustrated in FIG. 6. Therefore, in the producing process, after forming the first interlayer insulating film 32, the source contact hole CHS, the first terminal contact hole CHT1, and the first pixel contact hole CHP1 can be formed in the first interlayer insulating film 32 in the same process step. If the intermediate electrode 36 is not formed and the pixel electrode 25 is directly connected to the drain electrode 24C, the process step of forming contact holes in the first interlayer insulating film 32, the second interlayer insulating film 33, and the planarizing film 34 is necessary. In this respect, according to this embodiment, the first pixel contact hole CHP1 can be formed in the first interlayer insulating film 32 in the same process step of forming the source contact hole CHS and the first terminal contact hole CHT1 in the first interlayer insulating film 32. Accordingly, the number of times the first interlayer insulating film 32 is processed can be reduced.

The liquid crystal panel 11 has the configuration previously described and a method of producing the liquid crystal panel 11 will be described next. The method of producing the liquid crystal panel 11 includes an opposed substrate producing process of producing the opposed substrate 20 (a second substrate producing process), an array substrate producing process of producing the array substrate 21 (a first substrate producing process), and a bonding process of bonding the opposed substrate 20 and the array substrate 21. The array substrate producing process will be described with reference to FIGS. 12A to 23B.

FIGS. 12A to 12C, FIGS. 15A to 15C, FIGS. 18A to 18C, FIGS. 21A and 21B illustrate steps of forming the TFT 24, the pixel electrode 25, the common electrode 28, and the touch line 30 illustrated in FIG. 6. FIGS. 13A to 13C, FIGS. 16A to 16C, FIGS. 19A to 19C, FIGS. 22A and 22B illustrate steps of forming the first terminal 37α illustrated in FIG. 10. FIGS. 14A to 14C, FIGS. 17A to 17C, FIGS. 20A to 20C, FIGS. 23A and 23B illustrate steps of forming the terminal 1 illustrated in FIG. 11. The terminals 37 of this embodiment include the first terminal 37α but not include the terminal 1. Therefore, the steps of forming the terminal 1 will be described just for reference.

The array substrate producing process at least includes a first step of forming the first metal film M1 and patterning the first metal film M1, a second step of forming the gate insulating film 31 and the semiconductor film S1 and patterning the semiconductor film S1, a third step of patterning the gate insulating film 31, a fourth step of forming the second metal film M2 and patterning the second metal film M2, a fifth step of forming the first interlayer insulating film 32 and patterning the first interlayer insulating film 32, a sixth step of forming the third metal film M3 and patterning the third metal film M3, a seventh step of forming the second interlayer insulating film 33 and the planarizing film 34 and patterning the planarizing film 34, an eighth step of patterning the second interlayer insulating film 33, a ninth step of forming the first transparent electrode film T1 and the fourth metal film M4 and patterning the first transparent electrode film T1 and the fourth metal film M4, a tenth step of patterning the fourth metal film M4, an eleventh step of forming the third interlayer insulating film 35 and patterning the third interlayer insulating film 35, and a twelfth step of forming the second transparent electrode film T2 and patterning the second transparent electrode film T2.

The “patterning” means processing of films with the common photolithography method. Specifically, a photoresist film is formed on a target film to be processed, the photoresist film is exposed with light by an exposing device via a photomask having a predefined opening pattern, the photoresist film is developed, and the target film to be processed is processed with etching via the developed photoresist film and thus, the target film to be processed is processed with patterning.

In the first step, as illustrated with a double-dashed dotted line in FIGS. 12A, 13A, and 14A, the first metal film M1 is formed on the glass substrate 21GS of the array substrate 21. The formed first metal film M1 is patterned with the common photolithography method. With the first metal film M1 being pattered, the gate electrode 24A and the gate line 26 are formed in the display area AA as illustrated in FIG. 12A. On the other hand, in the driver arrangement area, where the driver 12 is arranged, and the flexible substrate arrangement area, where the flexible substrate 13 is arranged, of the non-display area NAA, the first metal film M1 is removed as illustrated in FIG. 13A. With the terminals 37 including the terminal 1, the first metal film portion 2 of the terminal 1 is formed as illustrated in FIG. 14A.

In the second step, the gate insulating film 31 is formed on the first metal film M1 (refer to FIGS. 12B, 13B, and 14B). As illustrated with a double-dashed dotted line in FIGS. 12B, 13B, and 14B, the semiconductor film S1 is formed on the gate insulating film 31. The formed semiconductor film S1 is patterned with the common photolithography method. With the semiconductor film S1 being patterned, the semiconductor section 24D is formed in the display area AA as illustrated in FIG. 12B. On the other hand, in the driver arrangement area and the flexible substrate arrangement area of the non-display area NAA, the semiconductor film S1 is removed as illustrated in FIGS. 13B and 14B.

In the third step, the gate insulating film 31 is pattered with common photolithography method. With the terminals 37 including the terminal 1, the contact hole 5 is formed in a portion of the gate insulating film 31 overlapping the first metal film portion 2 as illustrated in FIG. 14C. In the display area AA, the gate insulating film 31 is not processed. In the driver arrangement area and the flexible substrate arrangement area of the non-display area NAA, the gate insulating film 31 is not processed.

In the fourth step, as illustrated with a double-dashed dotted line in FIGS. 12C, 13C, and 14D, the second metal film M2 is formed on the semiconductor film S1. The formed second metal film M2 is patterned with the common photolithography method. With the second metal film M2 being patterned, the source electrode 24B, the drain electrode 24C, and the lower layer line 27A are formed in the display area AA as illustrated in FIG. 12C. On the other hand, in the driver arrangement area and the flexible substrate arrangement area of the non-display area NAA, the second metal film portion 37α1 of the first terminal 37α is formed as illustrated in FIG. 13C. With the terminals 37 including the terminal 1, the second metal film portion 3 of the terminal 1 is formed as illustrated in FIG. 14D. The second metal film portion 3 is connected to the first metal film portion 2 via the contact hole 5.

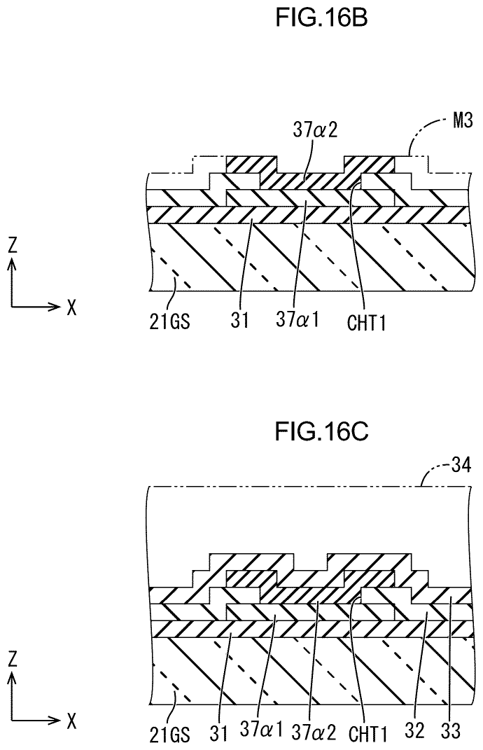

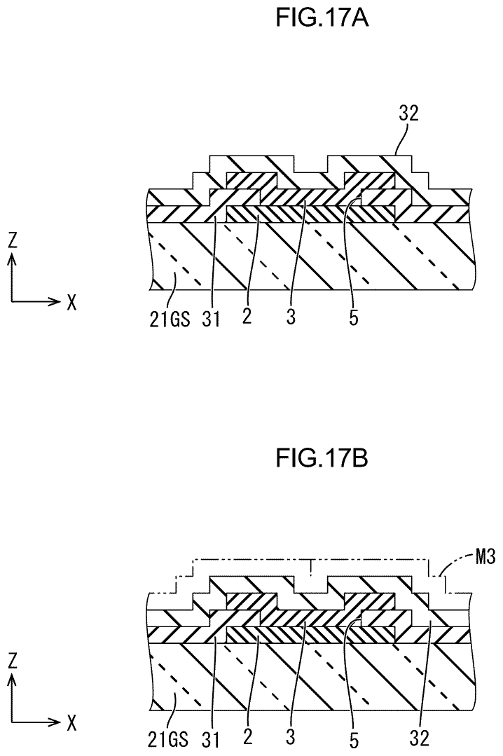

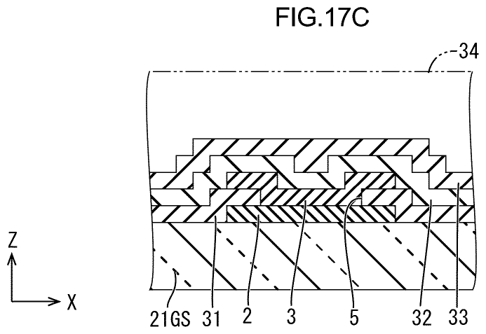

In the fifth step, the first interlayer insulating film 32 is patterned with the common photolithography method. The first interlayer insulating film 32 is patterned with dry etching since the first interlayer insulating film 32 includes silicon oxide. After patterning the first interlayer insulating film 32, in the display area AA, the source contact hole CHS is formed in a portion of the first interlayer insulating film 32 overlapping the source electrode 24B and the first pixel contact hole CHP1 is formed in a portion of the first interlayer insulating film 32 overlapping the drain electrode 24C. On the other hand, in the non-display area NAA, as illustrated in FIG. 16A, the first terminal contact hole CHT1 is formed in a portion of the first interlayer insulating film 32 overlapping the second metal film portion 37α1. With the terminals 37 including the terminal 1, the first interlayer insulating film 32 is not processed near the terminal 1 as illustrated in FIG. 17A.

In the sixth step, as illustrated with a double-dashed dotted line in FIGS. 15B, 16B, and 17B, the third metal film M3 is formed on the first interlayer insulating film 32. The formed third metal film M3 is patterned with the common photolithography method. With the third metal film M3 being patterned, the upper layer line 27B and the intermediate electrode 36 are formed in the display area AA as illustrated in FIG. 15B. The upper layer line 27B is connected to the source electrode 24B via the source contact hole CHS in the first interlayer insulating film 32. On the other hand, in the driver arrangement area and the flexible substrate arrangement area of the non-display area NAA, the third metal film portion 37α2 of the first terminal 37α is formed as illustrated in FIG. 16B. The third metal film portion 37α2 is connected to the second metal film portion 37α1 via the first terminal contact hole CHT1 in the first interlayer insulating film 32. With the terminals 37 including the terminal 1, the third metal film M3 is removed near the terminal 1 as illustrated in FIG. 17B.

In the seventh step, the second interlayer insulating film 33 is formed on the third metal film M3 and the planarizing film 34 is formed on the second interlayer insulating film 33 (refer to FIGS. 15C, 16C, and 17C). The planarizing film 34 out of the formed second interlayer insulating film 33 and the planarizing film 34 is selectively patterned with the common photolithography method. After patterning the planarizing film 34, in the display area AA, a portion of the second pixel contact hole CHP2 is formed in a portion of the planarizing film 34 overlapping the intermediate electrode 36 as illustrated in FIG. 15C. On the other hand, in the driver arrangement area and the flexible substrate arrangement area of the non-display area NAA, the planarizing film 34 is removed as illustrated in FIGS. 16C and 17C.

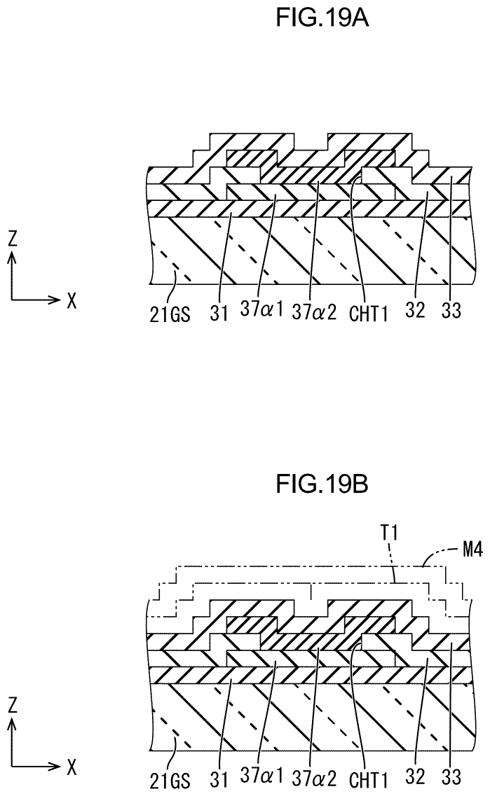

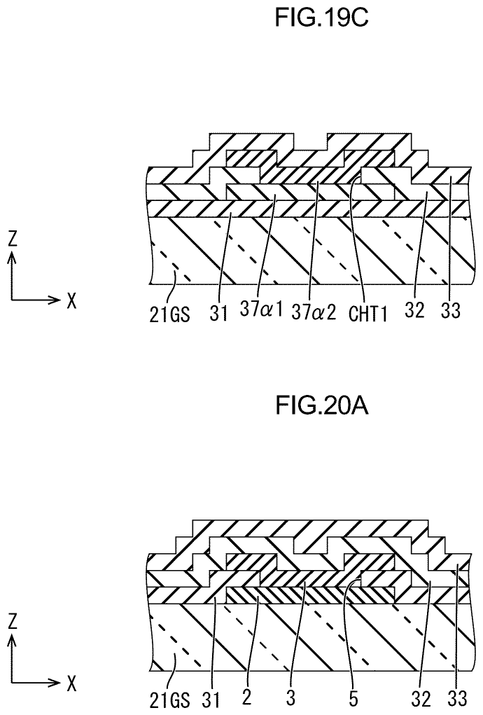

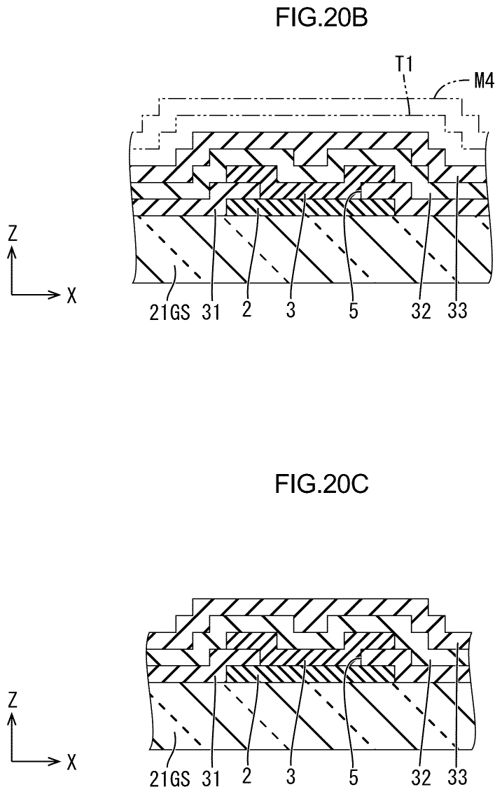

In the eighth step, the second interlayer insulating film 33 is patterned with the common photolithography method. After patterning the second interlayer insulating film 33, in the display area AA, the rest portion of the second pixel contact hole CHP2 is formed in a portion of the second interlayer insulating film 33 overlapping the intermediate electrode 36 so as to be communicated with the portion of the second pixel contact hole CHP2 in the planarizing film 34 as illustrated in FIG. 18A. On the other hand, in the driver arrangement area and the flexible substrate arrangement area of the non-display area NAA, as illustrated in FIGS. 19A and 20A, the second interlayer insulating film 33 is not processed.

In the ninth step, the first transparent electrode film T1 is formed on the planarizing film 34. Then, the fourth metal film M4 is formed on the first transparent electrode film T1 (refer to FIGS. 18B, 19B, and 20B). The formed first transparent electrode film T1 and the fourth metal film M4 are patterned with the common photolithography method. With the first transparent electrode film T1 and the fourth metal film M4 being patterned, the touch line 30 and the pixel electrode 25 are formed in the display area AA as illustrated in FIG. 18B. The pixel electrode 25 is connected to the intermediate electrode 36 via the second pixel contact hole CHP2. At this time, the pixel electrode 25 includes a portion of the fourth metal film M4 over an entire area thereof. The touch line 30 is insulated from the source line 27 (the upper layer line 27B), which overlaps the touch line 30, by the second interlayer insulating film 33 and the planarizing film 34. On the other hand, in the driver arrangement area and the flexible substrate arrangement area of the non-display area NAA, the first transparent electrode film T1 and the fourth metal film M4 are removed as illustrated in FIGS. 19B and 20B.

In the tenth step, the fourth metal film M4 out of the first transparent electrode film T1 and the fourth metal film M4, which are formed in the ninth step, is selectively patterned with the common photolithography method. After patterning the fourth metal film M4, the light blocking portion 25A of the pixel electrode 25 is formed as illustrated in FIG. 18C. At this time, in a portion of the fourth metal film M4 configured as the pixel electrode 25, a portion that does not overlap the intermediate electrode 36 is selectively removed and a portion that overlaps the intermediate electrode 36 remains. Accordingly, the pixel electrode 25 including the light blocking portion 25A is formed. On the other hand, in the driver arrangement area and the flexible substrate arrangement area of the non-display area NAA, any process is not performed in the tenth step since the first transparent electrode film T1 and the fourth metal film M4 are removed in the ninth step as illustrated in FIGS. 19C and 20C.

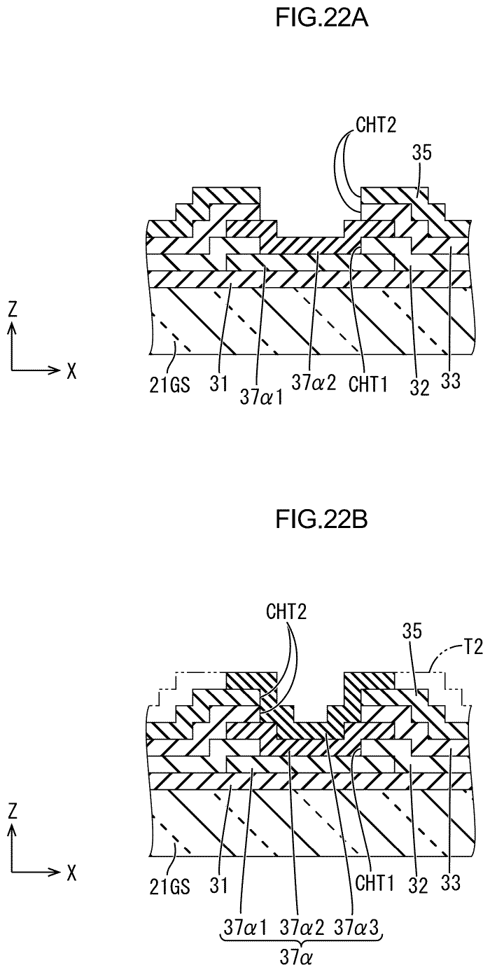

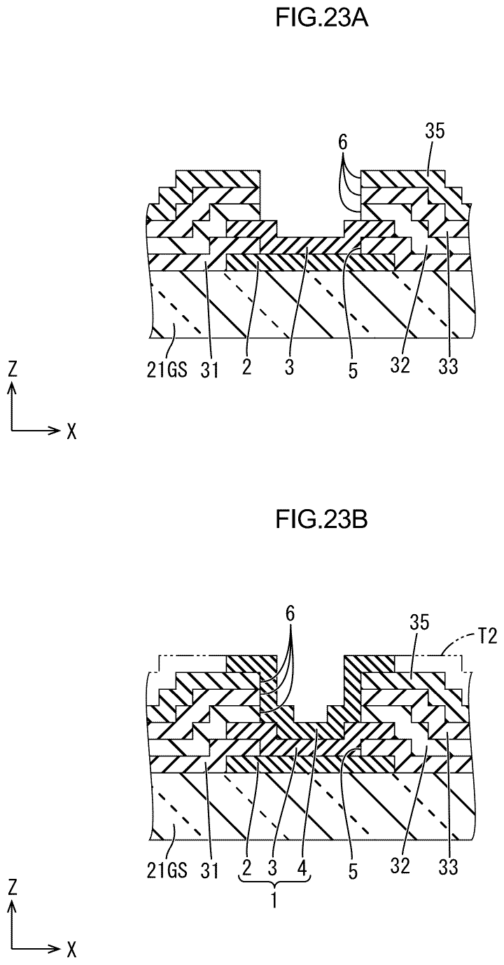

In the eleventh step, the third interlayer insulating film 35 is patterned with the common photolithography method. After patterning the third interlayer insulating film 35, in the display area AA, the touch contact hole CHTP is formed in a portion of the third interlayer insulating film 35 overlapping a portion of the touch line 30 as illustrated in FIG. 21A. On the other hand, in the driver arrangement area and the flexible substrate arrangement area of the non-display area NAA, the second interlayer insulating film 33 is processed with etching in addition to the third interlayer insulating film 35 as illustrated in FIG. 22A, and the second terminal contact holes CHT2 are formed in the portions of the second interlayer insulating film 33 and the third interlayer insulating film 35 overlapping the third metal film portion 37α2 such that the second terminal contact holes CHT2 in the second interlayer insulating film 33 and the third interlayer insulating film 35 communicate. With the terminals 37 including the terminal 1, the first interlayer insulating film 32 and the second interlayer insulating film 33 are processed with etching in addition to the third interlayer insulating film 35, as illustrated in FIG. 23A, the contact hole 6 is formed in the portions of the first interlayer insulating film 32, the second interlayer insulating film 33, and the third interlayer insulating film 35 overlapping the second metal film portion 3.

In the twelfth step, the second transparent electrode film T2 is formed on the third interlayer insulating film 35 (refer to FIGS. 21B, 22B, and 23B). The formed second transparent electrode film T2 is patterned with the common photolithography method. After patterning the second transparent electrode film T2, the common electrode 28 is formed in the display area AA as illustrated in FIG. 21B. With the common electrode 28 being divided by the dividing openings 28A, the touch electrodes 29 are formed (refer to FIG. 1). The touch electrodes 29 are connected to the respective target touch lines 30 via the touch contact holes CHTP. On the other hand, in the driver arrangement area and the flexible substrate arrangement area of the non-display area NAA, the transparent electrode portion 37α3 is formed in a portion overlapping the third metal film portion 37α2 as illustrated in FIG. 22B. The transparent electrode portion 37α3 is connected to the third metal film portion 37α2 via the second terminal contact holes CHT2 in the second interlayer insulating film 33 and the third interlayer insulating film 35. With the terminals 37 including the terminal 1, the transparent electrode portion 4 is formed to overlap the second metal film portion 3 as illustrated in FIG. 23B. The transparent electrode portion 4 is connected to the second metal film portion 3 via the contact hole 6 in the first interlayer insulating film 32, the second interlayer insulating film 33, and the third interlayer insulating film 35.

As previously described, in the method of producing the liquid crystal panel 11 according to this embodiment, with the first interlayer insulating film 32 being patterned in the fifth step, the source contact hole CHS and the first pixel contact hole CHP1 are formed in the display area AA and the first terminal contact hole CHT1 is formed in the non-display area NAA. Namely, the source contact hole CHS, the first pixel contact hole CHP1, and the first terminal contact hole CHT1 are collectively formed in the first interlayer insulating film 32 in the same process step (with etching one time). In this respect, with the terminals 37 including the terminal 1, the contact hole 6 needs to be partially formed in the first interlayer insulating film 32 in the eleventh step and therefore, the first interlayer insulating film 32 is necessarily processed with etching twice in the fifth step and the eleventh step (refer to FIGS. 15A and 22A). In this embodiment, the number of times the first interlayer insulating film 32 is processed with etching is one and can be reduced compared to the method of producing the display device having a configuration in which the terminals 37 include the terminal 1.

As previously described, the liquid crystal panel 11 (the display device) of this embodiment includes the display area AA (the display section) displaying an image, the non-display area (the non-display section) displaying no image, the TFTs 24 (the switching components) disposed in the display area AA, the upper layer lines 27B (the first line) disposed in the display area AA and connected to the TFTs 24, respectively, and the first terminals 37α disposed in the non-display area NAA. The TFT 24 includes the gate electrode 24A (the first electrode) that is a portion of the first metal film M1 (the first conductive film), the semiconductor section 24D that is a portion of the semiconductor film S1 included in a layer upper than the first metal film M1 via the gate insulating film 31 (the first insulating film), the source electrode 24B (the second electrode) that is a portion of the second metal film M2 (the second conductive film) included in a layer upper than the semiconductor film S1 and is connected to the semiconductor section 24D, and the drain electrode 24C (the third electrode) that is a portion of the second metal film M2 different from the portion of the second metal film M2 configured as the source electrode 24B and is connected to the semiconductor section 24D. The upper layer line 27B is a portion of the third metal film M3 (the third conductive film) disposed in a layer upper than the second metal film M2 via the first interlayer insulating film 32 (the second insulating film). A portion of the upper layer line 27B is disposed to overlap the source electrode 24B. The first terminal 37α includes the second metal film portion 37α1 (the first terminal portion) and the third metal film portion 37α2 (the second terminal portion). The second metal film portion 37α1 is a portion of the second metal film M2 that is different from the portions of the second metal film M2 configured as the source electrode 24B and the drain electrode 24C. The third metal film portion 37α2 is a portion of the third metal film M3 that is different from the portion of the third metal film M3 configured as the upper layer line 27B. At least a portion of the third metal film portion 37α2 overlaps the second metal film portion 37α1. The first interlayer insulating film 32 includes the source contact hole CHS (the first contact hole) in a portion overlapping the upper layer line 27B and the source electrode 24B and includes the first terminal contact hole CHT1 (the second contact hole) in a portion overlapping the second metal film portion 37α1 and the third metal film portion 37α2.

The TFT 24 disposed in the display area AA is driven when a potential higher than the threshold voltage is supplied to the gate electrode 24A. Then, the signal supplied to the source electrode 24B from the upper layer line 27B is supplied to the drain electrode 24C via the semiconductor section 24D. In the display area AA, the upper layer line 27B, which is a portion of the third metal film M3, is connected to the source electrode 24B, which is a portion of the second metal film M2, via the source contact hole CHS in the first interlayer insulating film 32. In the non-display area NAA, the third metal film portion 37α2, which is a portion of the third metal film M3, is connected to the second metal film portion 37α1, which is a portion of the second metal film M2, via the first terminal contact hole CHT1 in the first interlayer insulating film 32. The second metal film portion 37α1 and the third metal film portion 37α2 are configured as the first terminal 37α. Therefore, in the producing process, after forming the first interlayer insulating film 32, the source contact hole CHS and the first terminal contact hole CHT1 can be formed in the first interlayer insulating film 32 in the same process step. This reduces the number of times the first interlayer insulating film 32 is processed compared to the previous method.

This embodiment further includes the lower layer line 27A (the second line) disposed in the display area AA. The lower layer line 27A is a portion of the second metal film M2 that is different from the portions of the second metal film M2 configured as the source electrode 24B, the drain electrode 24C, and the second metal film portion 37α1. The lower layer line 27A is continuous to the source electrode 24B and extends along the upper layer line 27B and is disposed to overlap the upper layer line 27B via the first interlayer insulating film 32. The lower layer line 27A that is continuous to the source electrode 24B has a potential same as that of the upper layer line 27B. This reduces the resistance of the lower layer line 27A and the upper layer line 27B. If one of the lower layer line 27A and the upper layer line 27B is disconnected, the signals can be transferred via the other one and redundancy can be achieved. The lower layer line 27A, which is a portion of the second metal film M2, extends along the upper layer line 27B, which is a portion of the third metal film M3, and is disposed to overlap the upper layer line 27B via the first interlayer insulating film 32. Therefore, the lower layer line 27A and the upper layer line 27B can be disposed in a small space in the display area AA and the aperture ratio of the pixels can be preferably increased.

This embodiment further includes the intermediate electrode 36 (the fourth electrode) that is disposed in the display area AA and connected to the drain electrode 24C and the pixel electrode 25 that is disposed in the display area AA and connected to the intermediate electrode 36. The intermediate electrode 36 is a portion of the third metal film M3 that is different from the portion of the third metal film M3 configured as the upper layer line 27B. At least a portion of the intermediate electrode 36 is disposed to overlap the drain electrode 24C. The pixel electrode 25 includes a portion of the first transparent electrode film T1 and a portion of the fourth metal film M4 (the fourth conductive film) that are included in layers upper than the third metal film M3 via the second interlayer insulating film 33 and the planarizing film 34 (the third insulating film). A portion of the pixel electrode 25 overlaps the intermediate electrode 36. The first interlayer insulating film 32 includes the first pixel contact hole CHP1 (the third contact hole) in a portion overlapping the drain electrode 24C and the intermediate electrode 36. The second interlayer insulating film 33 and the planarizing film 34 (the third insulating film) include the second pixel contact holes CHP2 (the fourth contact hole) in portions overlapping both of the intermediate electrode 36 and the pixel electrode 25. The signal supplied to the drain electrode 24C upon driving of the TFT 24 is supplied to the pixel electrode 25 via the intermediate electrode 36. The pixel electrode 25 is charged at a potential of the supplied signal. The intermediate electrode 36, which is a portion of the third metal film M3, is connected to the drain electrode 24C, which is a portion of the second metal film M2, via the first pixel contact hole CHP1 in the first interlayer insulating film 32. The pixel electrode 25, which includes a portion of the first transparent electrode film T1 and a portion of the fourth metal film M4 (the fourth conductive film), is connected to the intermediate electrode 36, which is a portion of the third metal film M3, via the second pixel contact holes CHP2 in the second interlayer insulating film 33 and the planarizing film 34 (the third insulating film). In the producing process, after forming the first interlayer insulating film 32, the source contact hole CHS, the first terminal contact hole CHT1, and the first pixel contact hole CHP1 can be formed in the first interlayer insulating film 32 in the same process step. If the intermediate electrode 36 is not included and the pixel electrode 25 is directly connected to the drain electrode 24C, a process step of forming contact holes in the first interlayer insulating film 32, and the second interlayer insulating film 33 and the planarizing film 34 (the third insulating film) is necessary. However, in this embodiment, the first pixel contact hole CHP1 can be formed in the first interlayer insulating film 32 in the same process step of forming the source contact hole CHS and the first terminal contact hole CHT1 in the first interlayer insulating film 32. This reduces the number of times the first interlayer insulating film 32 is processed.

The method of producing the liquid crystal panel 11 according to this embodiment includes forming the first metal film M1, patterning the first metal film M1 and forming the gate electrode 24A in the display area AA displaying an image, forming the gate insulating film 31 in a layer upper than the first metal film M1, forming the semiconductor film S1 in a layer upper than the gate insulating film 31, patterning the semiconductor film S1 and forming the semiconductor section 24D that overlaps the gate electrode 24A, forming the second metal film M2 in a layer upper than the semiconductor film S1, patterning the second metal film M2 and forming the source electrode 24B connected to the semiconductor section 24D and the drain electrode 24C connected to the semiconductor section 24D and forming the second metal film portion 37α1 in the non-display area NAA displaying no image, forming the first interlayer insulating film 32 in a layer upper than the second metal film M2, patterning the first interlayer insulating film 32 and forming the source contact hole CHS in a portion of the first interlayer insulating film 32 overlapping the source electrode 24B and forming the first terminal contact hole CHT1 in a portion of the first interlayer insulating film 32 overlapping the second metal film portion 37α1, forming the third metal film M3 in a layer upper than the first interlayer insulating film 32, patterning the third metal film M3 and forming the upper layer line 27B in the display area AA such that a portion of the upper layer line 27B overlaps the source electrode 24B and the source contact hole CHS and forming the third metal film portion 37α2 in the non-display area NAA such that at least a portion of the third metal film portion 372 overlaps the second metal film portion 37α1 and the first terminal contact hole CHT1. The third metal film portion 37α2 and the second metal film portion 37α1 are configured as the first terminal 37α.

With the semiconductor film S1 being formed and patterned, the semiconductor section 24D is formed. The semiconductor section 24D is disposed to overlap the gate electrode 24A, which is a portion of the first metal film M1, via the gate insulating film 31. With the second metal film M2 being formed and patterned, the source electrode 24B and the drain electrode 24C are formed in the display area AA and the second metal film portion 37α1 is formed in the non-display area NAA. The source electrode 24B and the drain electrode 24C are connected to the semiconductor section 24D. With the first interlayer insulating film 32 being formed and patterned, the source contact hole CHS is formed in the display area AA and the first terminal contact hole CHT1 is formed in the non-display area NAA. With the third metal film M3 being formed and patterned, the upper layer line 27B is formed in the display area AA and the third metal film portion 37α2 is formed in the non-display area NAA. The upper layer line 27B is connected to the source electrode 24B via the overlapping source contact hole CHS. The third metal film portion 37α2 is connected to the second metal film portion 37α1 via the overlapping first terminal contact hole CHT1. The third metal film portion 37α2 and the second metal film portion 37α1 are configured as the first terminal 37α. Thus, in the process step of patterning the first interlayer insulating film 32, the source contact hole CHS and the first terminal contact hole CHT1 are formed in the first interlayer insulating film 32. Thus, the number of times the first interlayer insulating film 32 is processed can be reduced compared to the previous method.

### Second Embodiment

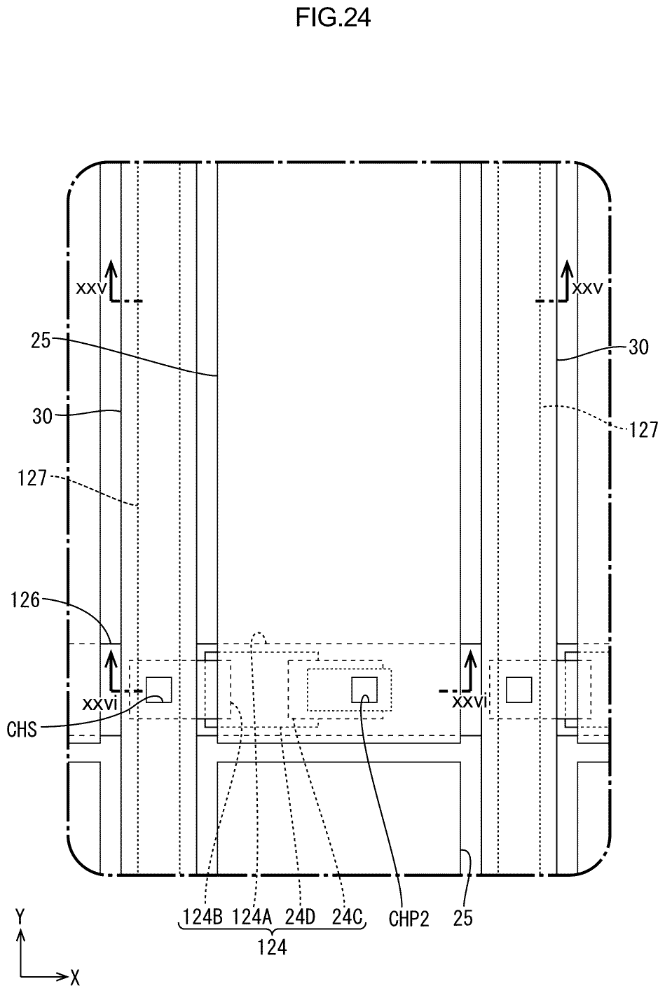

A second embodiment will be described with reference to FIGS. 24 to 26. The second embodiment differs from the first embodiment in a configuration of a source line 127. Configuration, operations, and effects similar to those of the first embodiment may not be described.

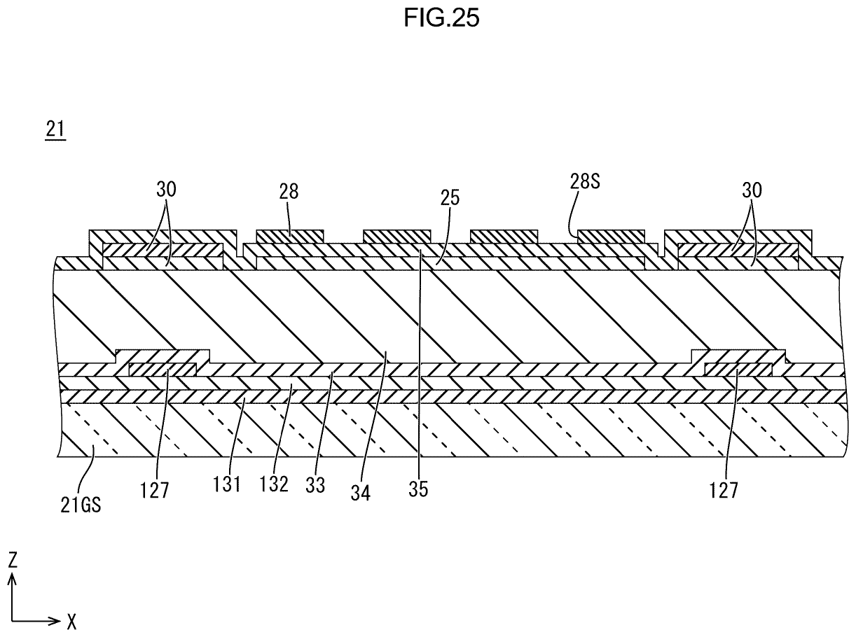

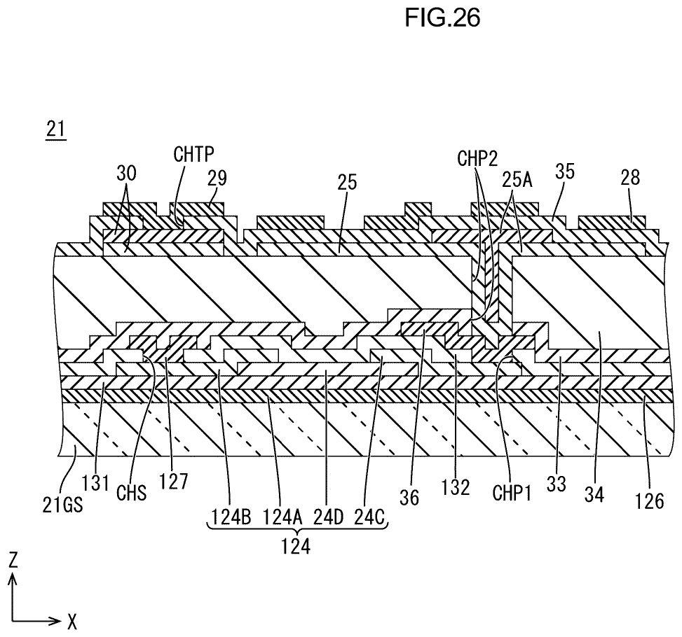

As illustrated in FIGS. 24 and 25, the source line 127 (the first line) of this embodiment has a single layer structure and is a portion of the third metal film M3. Namely, the source line 127 of this embodiment includes only the upper layer line 27B (refer to FIG. 4) of the first embodiment. As illustrated in FIGS. 24 and 26, the source line 127, which is a portion of the third metal film M3, is connected to a source electrode 124B, which is a portion of the second metal film M2, via a source contact hole CHS in a first interlayer insulating film 132. The first interlayer insulating film 132 is disposed between the source line 127 and the source electrode 124B. As illustrated in FIG. 26, the source line 127 crosses a gate line 126 (the third line), which is a portion of the first metal film M1, via a gate insulating film 131 and the first interlayer insulating film 132. In the first embodiment, the lower layer line 27A of the source line 27 is a portion of the second metal film M2 and crosses the gate line 26 via the gate insulating film 31 (refer to FIG. 6). Therefore, in this embodiment, a distance between intersections of the gate lines 126 and the source lines 127 is longer than that of the first embodiment by the first interlayer insulating film 132. With such a configuration, a parasitic capacitance that may be created between the gate line 126 and the source line 127 can be reduced.

As previously described, according to this embodiment, the gate lines 126 (the third line) are disposed in the display area AA. The gate line 126 is a portion of the first metal film M1 that is different from the portion of the first metal film M1 configured as the gate electrode 124A and is continuous to the gate electrode 124A. The gate line 126 crosses the source line 127 (the first line) via the gate insulating film 131 and the first interlayer insulating film 132. With the gate line 126, the gate electrode 124A can be supplied with a potential of a threshold voltage of the TFT 124 or higher. The gate lines 126, which are portions of the first metal film M1, and the source lines 127, which are portions of the third metal film M3, cross and the gate insulating film 131 and the first interlayer insulating film 132 are disposed between the gate lines 126 and the source lines 127. With such a configuration, a distance between intersections of the gate lines 126 and the source lines 127 is longer than that in a configuration in which the source lines 127 are portions of the second metal film M2. Therefore, a parasitic capacitance that may be created between the gate line 126 and the source line 127 can be reduced.

### Third Embodiment

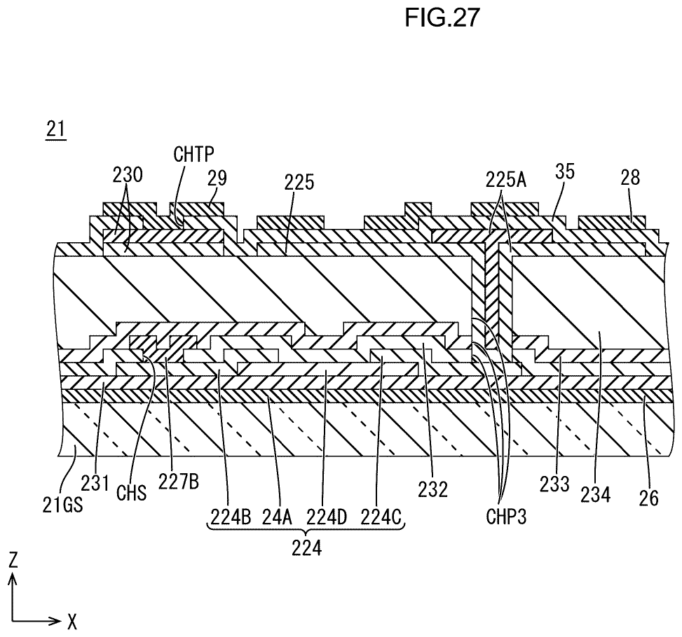

A third embodiment will be described with reference to FIGS. 27 to 29C. The third embodiment has the configuration of the first embodiment but not include the intermediate electrodes 36. Configuration, operations, and effects similar to those of the first embodiment may not be described.

As illustrated in FIG. 27, a drain electrode 224C of TFT 224 of this embodiment is directly connected to a pixel electrode 225 without having the intermediate electrode 36 (refer to FIG. 6) of the first embodiment therebetween. Specifically, a portion of the pixel electrode 225 is disposed to overlap an end portion of the drain electrode 224C opposite from an end portion close to a semiconductor section 224D. A first interlayer insulating film 232, a second interlayer insulating film 233, and a planarizing film 234 that are disposed between the drain electrode 224C and the pixel electrode 225 include the third pixel contact holes CHP3 (the fifth contact hole) that communicate each other through the three films. The drain electrode 224C and the pixel electrode 225 are connected via the third pixel contact holes CHP3.

With the intermediate electrode 36, which is a portion of the third metal film M3, being connected to the drain electrode 224C and the pixel electrode 225 (refer to FIG. 6) like the first embodiment, the intermediate electrode 36 and the upper layer line 27B, which is a portion of the third metal film M3, may be short-circuited and this may result in poor manufacturing yield. In this embodiment, the intermediate electrode 36, which a portion of the third metal film M3, is not disposed to overlap the drain electrode 224C and therefore short-circuit is less likely to be caused in an upper layer line 227B and this improves manufacturing yield.

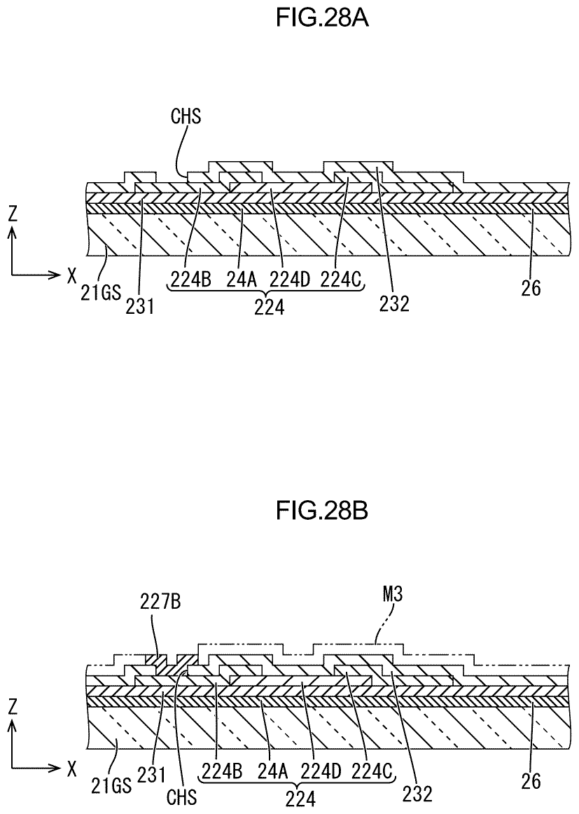

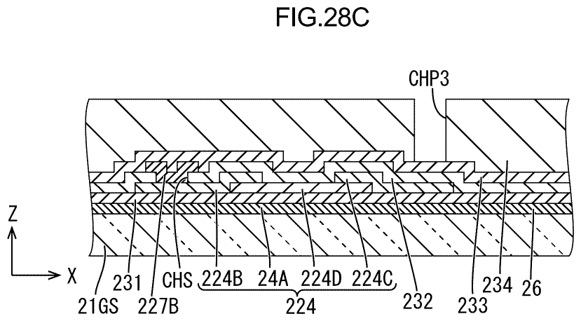

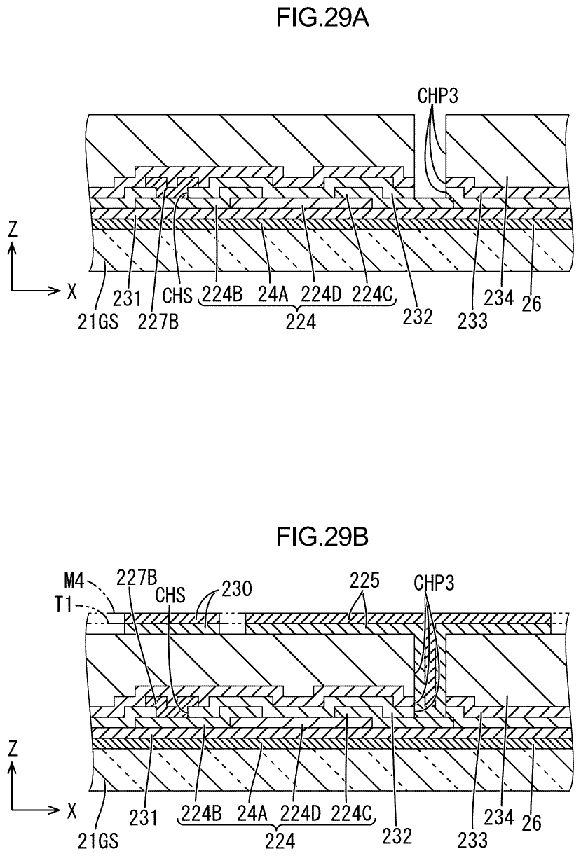

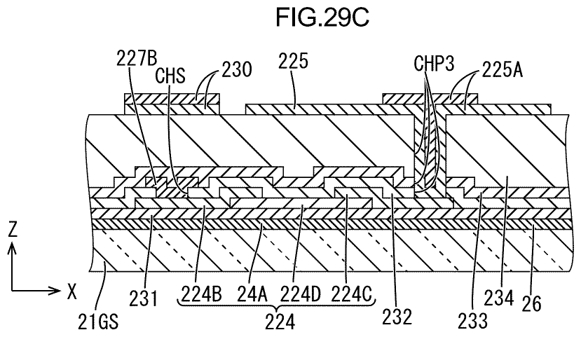

Next, a process of producing an array substrate included in a method of producing the liquid crystal panel 11 will be described with reference to FIGS. 28A to 29C. FIGS. 28A to 29C illustrate process steps of producing the TFT 224, the pixel electrode 225, and a touch line 230 illustrated in FIG. 27 and the process steps will be described below. Among process steps (the first step to the twelfth step) included in the process of producing the array substrate, the fifth step to ninth step, which are different from those of the first embodiment, will be described. In the following, the process steps of producing the first terminal 37α (refer to FIGS. 13A to 13C, 16A to 16C, 19A to 19C, 22A, and 22B) that are same as those of the first embodiment will not be described.

After the second metal film M2 is patterned through the fourth step, the fifth step is performed. In the fifth step, the first interlayer insulating film 232 is patterned with the common photolithography method. With the first interlayer insulating film 232 being patterned, in the display area AA, the source contact hole CHS is formed in a portion of the first interlayer insulating film 232 overlapping the source electrode 224B as illustrated in FIG. 28A. At this time, a hole is not formed in a portion of the first interlayer insulating film 232 overlapping the drain electrode 242C.

In the sixth step, as illustrated with a double-dashed dotted line in FIG. 28B, the third metal film M3 is formed on the first interlayer insulating film 232. The formed third metal film M3 is patterned with the common photolithography method. With the third metal film M3 being patterned, the upper layer line 227B is formed in the display area AA as illustrated in FIG. 28B. The upper layer line 227B is connected to the source electrode 224B via the source contact hole CHS in the first interlayer insulating film 232.

In the seventh step, the second interlayer insulating film 233 is formed on the third metal film M3 and the planarizing film 234 is formed on the second interlayer insulating film 233 (refer to FIG. 28C). The planarizing film 234 out of the formed second interlayer insulating film 233 and the planarizing film 234 is selectively patterned with the common photolithography method. After patterning the planarizing film 234, in the display area AA, a portion of the third pixel contact hole CHP3 is formed in a portion of the planarizing film 234 overlapping the drain electrode 224C as illustrated in FIG. 28C.

In the eighth step, the first interlayer insulating film 231 and the second interlayer insulating film 233 are patterned with the common photolithography method. After patterning the first interlayer insulating film 231 and the second interlayer insulating film 233, in the display area AA, the rest portion of the third pixel contact hole CHP3 is formed in portions of the first interlayer insulating film 231 and the second interlayer insulating film 233 overlapping the drain electrode 224C so as to be communicated with the portion of the second pixel contact hole CHP2 in the planarizing film 234 as illustrated in FIG. 29A.

In the ninth step, the first transparent electrode film T1 is formed on the planarizing film 234. Then, the fourth metal film M4 is formed on the first transparent electrode film T1 (refer to FIG. 29B). The formed first transparent electrode film T1 and the fourth metal film M4 are patterned with the common photolithography method. With the first transparent electrode film T1 and the fourth metal film M4 being patterned, in the display area AA, the touch line 230 and the pixel electrode 225 are formed as illustrated in FIG. 29B. The pixel electrode 225 is directly connected to the drain electrode 224C via the third pixel contact hole CHP3. At this time, the pixel electrode 225 includes a portion of the fourth metal film M4 over an entire area thereof. The touch line 230 is insulated from the upper layer line 227B, which overlaps the touch line 230, by the second interlayer insulating film 233 and the planarizing film 234. Then, with the tenth step being performed, the fourth metal film M4 is selectively patterned and a light blocking portion 225A of the pixel electrode 225 is formed as illustrated in FIG. 29C.

As previously described, this embodiment includes the pixel electrode 225 that is disposed in the display area AA and connected to the drain electrode 224C. The pixel electrode 225 includes portions of the first transparent electrode film T1 and the fourth metal film M4 (the fourth conductive film) that are included in layers upper than (above) the third metal film M3 via the second interlayer insulating film 233 and the planarizing film 234 (the third insulating film). The pixel electrode 225 partially overlaps the drain electrode 224C. The second interlayer insulating film 233 and the planarizing film 234 (the third insulating film) and the first interlayer insulating film 232 include the third pixel contact holes CHP3 (the fifth contact hole) in portions overlapping both of the drain electrode 224C and the pixel electrode 225. The third pixel contact holes CHP3 in the films are communicated with each other. The signal supplied to the drain electrode 224C upon the driving of the TFT 224 is supplied to the pixel electrode 225. The pixel electrode 225 is charged at a potential of the supplied signal. The pixel electrode 225, which includes portions of the first transparent electrode film T1 and the fourth metal film M4 (the fourth conductive film) are connected to the drain electrode 224C, which is a portion of the second metal film M2, via the third pixel contact holes CHP3 in the second interlayer insulating film 233 and the planarizing film 234 (the third insulating film) and the first interlayer insulating film 232. If an electrode, which is a portion of the third metal film M3, is disposed to overlap the drain electrode 224C and is connected to the drain electrode 224C and the pixel electrode 225, the electrode and the upper layer line 227B may be short-circuited and this may result in poor manufacturing yield. In this respect, any electrode, which is a portion of the third metal film M3, is not disposed to overlap the drain electrode 224C and this improves manufacturing yield.

### Fourth Embodiment

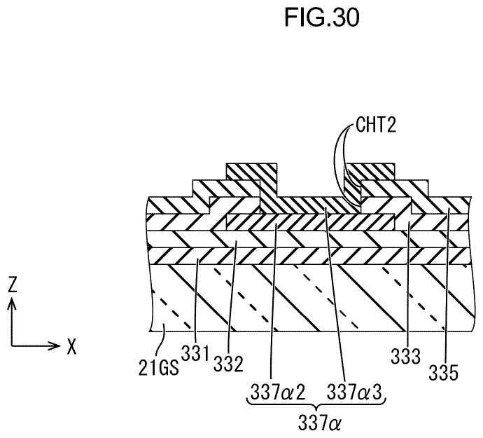

A fourth embodiment will be described with reference to FIGS. 30 to 32. The fourth embodiment differs from the first embodiment in a configuration of a first terminal 337α. Configuration, operations, and effects similar to those of the first embodiment may not be described.

As illustrated in FIG. 30, the first terminal 337α of this embodiment at least includes a third metal film portion 337α2 that is a portion of the third metal film M3 and a transparent electrode portion 337α3 that is a portion of the second transparent electrode film. The third metal film portion 337α2 and the transparent electrode portion 337α3 are connected via the second terminal contact holes CHT2 that are formed in a second interlayer insulating film 333 and a third interlayer insulating film 335 that are disposed between the third metal film portion 337α2 and the transparent electrode portion 337α3. The configuration of the first terminal 337α changes according to the configuration of a target extending line 40 to be connected. The extending line 40 is a line extending from the source line 27 in the display area AA or the circuit portion 14 in the non-display area NAA (refer to FIGS. 1 and 5). For instance, with the extending line 40 being a portion of the third metal film M3, the third metal film portion 337α2 of the first terminal 337α is directly continuous to the extending line 40. In such a configuration, the first terminal 337α includes the third metal film portion 337α2 and the transparent electrode portion 337α3.

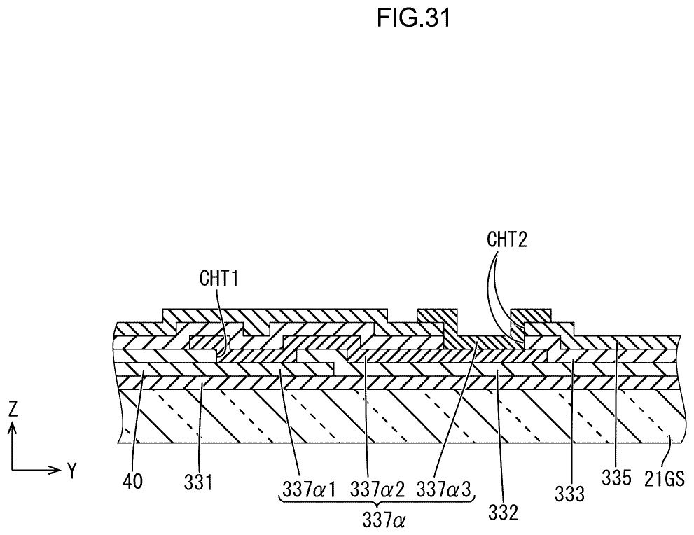

Furthermore, for instance, with the extending line 40 being a portion of the second metal film M2, as illustrated in FIG. 31, the first terminal 337α includes the second metal film portion 337α1, which is a portion of the second metal film M2. The extending line 40 is directly continuous to the second metal film portion 337α1 of the first terminal 337. The second metal film portion 337α1 is connected to the third metal film portion 337α2 via the first terminal contact hole CHT1 in the first interlayer insulating film 332. In such a configuration, the first terminal contact hole CHT1 does not overlap the second terminal contact hole CHT2.

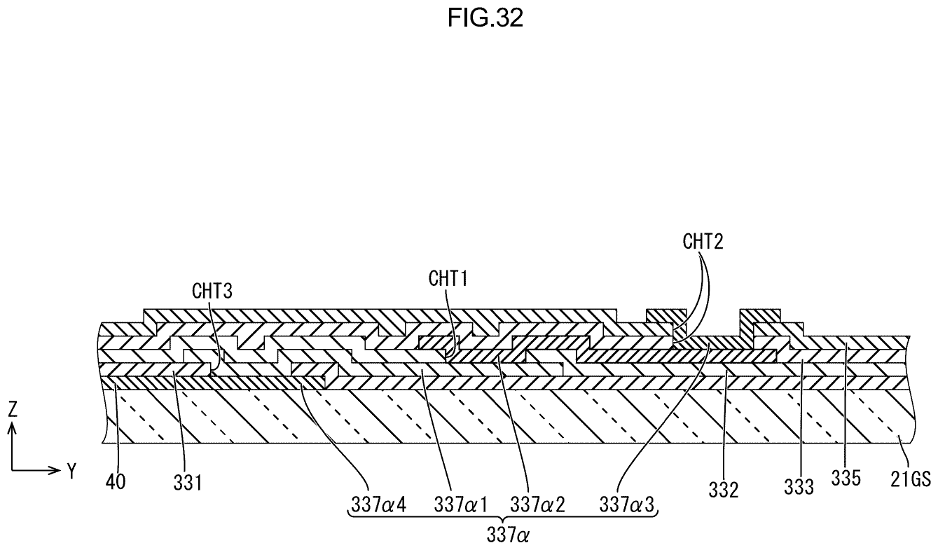

Furthermore, for instance, with the extending line 40 being a portion of the first metal film M1, as illustrated in FIG. 32, the first terminal 337 includes the second metal film portion 337α1, which is a portion of the second metal film M2, and a first metal film portion 337α4, which is a portion of the first metal film M1. The extending line 40 is directly continuous to the first metal film portion 337α4 of the first terminal 337α. The first metal film portion 337α4 is connected to the second metal film portion 337α1 via the third terminal contact hole CHT3 in the gate insulating film 331. The second metal film portion 337α1 is connected to the third metal film portion 337α2 via the first terminal contact hole CHT1 in the first interlayer insulating film 332. In such a configuration, the first terminal contact hole CHT1, the second terminal contact hole CHT2, and the third terminal contact hole CHT3 do not overlap each other.

In both of the configuration in which the extending line 40 is a portion of the second metal film M2 and the configuration in which the extending line 40 is a portion of the first metal film M1, the first interlayer insulating film 332 includes the first terminal contact hole CHT1 as illustrated in FIGS. 31 and 32. Therefore, in the producing process, the source contact hole CHS and the first terminal contact hole CHT1 can be formed in the first interlayer insulating film 332 in the fifth step described in the first embodiment. Accordingly, the number of times the first interlayer insulating film 332 is processed can be reduced similarly to the first embodiment. With the extending line 40 including a portion of the first transparent electrode film T1 and a portion of the fourth metal film M4, the extending line 40 is connected to the third metal film portion 337α2 via the contact hole in the second interlayer insulating film 333. Therefore, additional contact holes need not be formed in the first interlayer insulating film 332.

### Fifth Embodiment

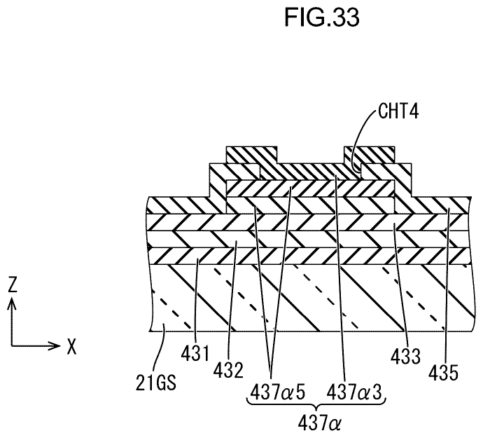

A fifth embodiment will be described with reference to FIGS. 33 to 36. The fifth embodiment differs from the first embodiment in a configuration of a first terminal 437α. Configuration, operations, and effects similar to those of the first embodiment may not be described.

As illustrated in FIG. 33, the first terminal 437α of this embodiment at least includes a layered film portion 437α5 that includes a portion of the first transparent electrode film T1 and a portion of the fourth metal film M4 and a transparent electrode portion 437α3 that is a portion of the second transparent electrode film. The layered film portion 437α5 and the transparent electrode portion 437α3 are connected via the fourth terminal contact hole CHT4 formed in a third interlayer insulating film 435 that is disposed between the layered film portion 437α5 and the transparent electrode portion 437α3. The configuration of the first terminal 437α changes according to the configuration of a target extending line 440 to be connected. The extending line 440 is a line extending from the source line 27 in the display area AA or the circuit portion 14 in the non-display area NAA (refer to FIGS. 1 and 5). For instance, with the extending line 440 including a portion of the first transparent electrode film T1 and a portion of the fourth metal film M4, the layered film portion 437α5 of the first terminal 437α is directly continuous to the extending line 440. In such a configuration, the first terminal 437α includes the layered film portion 437α5 and the transparent electrode portion 437α3.

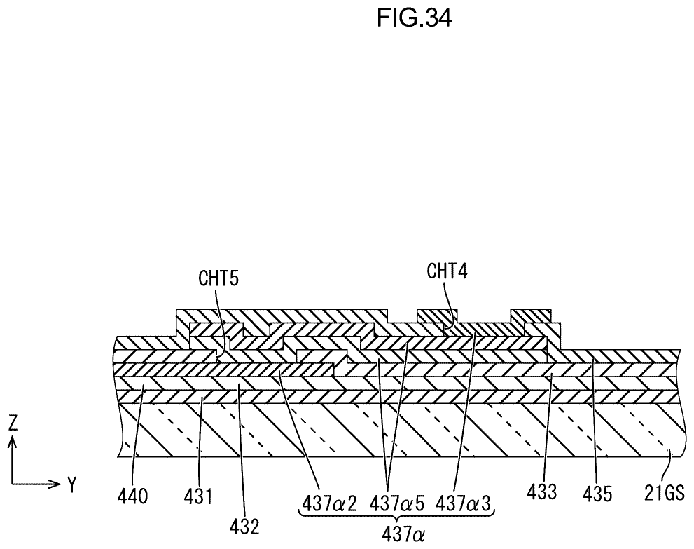

For instance, with the extending line 440 being a portion of the third metal film M3, as illustrated in FIG. 34, the first terminal 437α includes the third metal film portion 437α2, which is a portion of the third metal film M3. The extending line 440 is directly continuous to the third metal film portion 437α2 of the first terminal 437α. The third metal film portion 437α2 is connected to the layered film portion 437α5 via the fifth terminal contact hole CHT5 in the second interlayer insulating film 433. In such a configuration, the fifth terminal contact hole CHT5 does not overlap the fourth terminal contact hole CHT4.

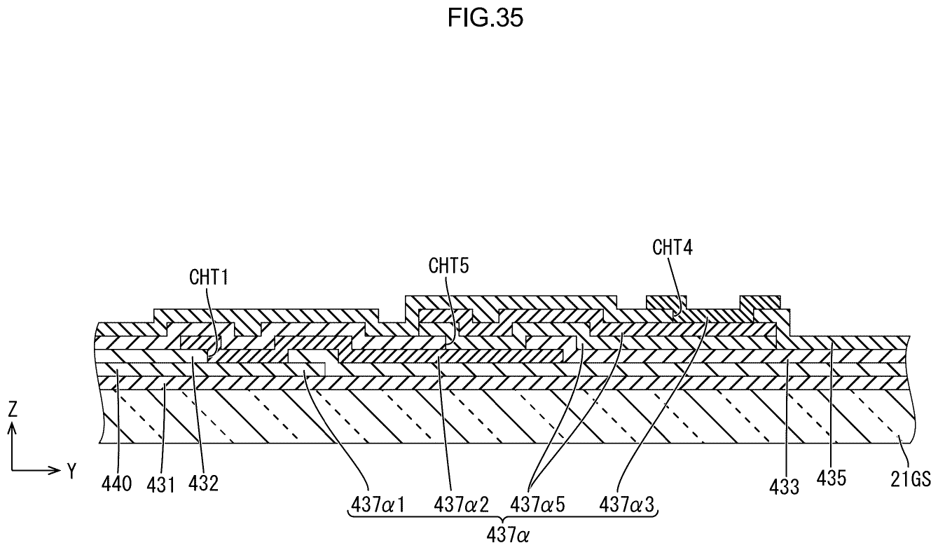

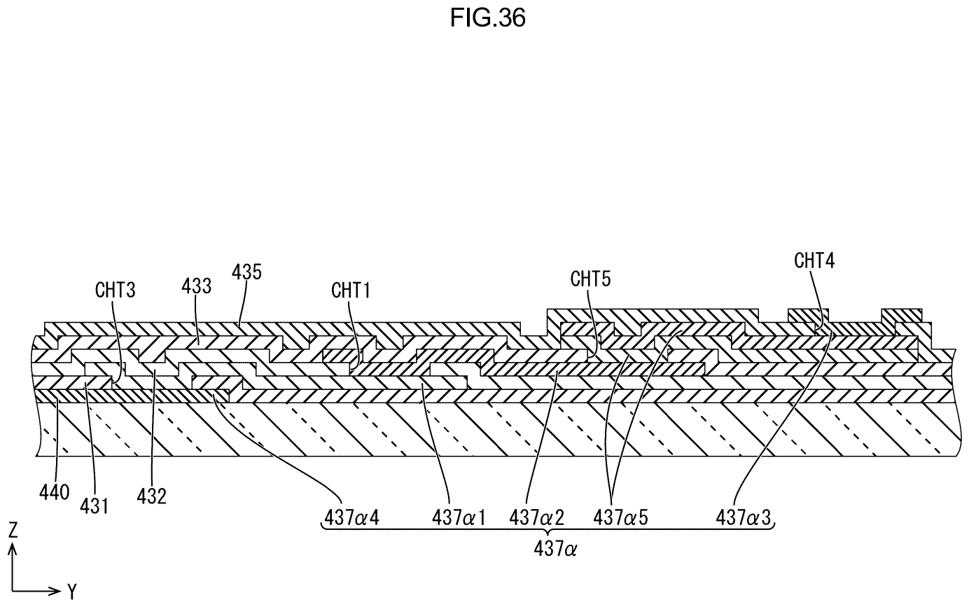

Furthermore, for instance, with the extending line 440 being a portion of the second metal film M2, as illustrated in FIG. 35, the first terminal 437α includes the second metal film portion 437α1, which is a portion of the second metal film M2. The extending line 440 is directly continuous to the second metal film portion 437α1 of the first terminal 437α. The second metal film portion 437α1 is connected to the third metal film portion 437α2 via the first terminal contact hole CHT1 in the first interlayer insulating film 432. In such a configuration, the first terminal contact hole CHT1 does not overlap the fourth terminal contact hole CHT4 and the fifth terminal contact hole CHT5.

Furthermore, for instance, with the extending line 440 being a portion of the first metal film M1, as illustrated in FIG. 36, the first terminal 437α includes the second metal film portion 437α1, which is a portion of the second metal film M2, and a first metal film portion 437α4, which is a portion of the first metal film M1. The extending line 440 is directly continuous to the first metal film portion 437α4 of the first terminal 437α. The first metal film portion 437α4 is connected to the second metal film portion 437α1 via the third terminal contact hole CHT3 in a gate insulating film 431. The second metal film portion 437α1 is connected to the third metal film portion 437α2 via the first terminal contact hole CHT1 in the first interlayer insulating film 432. In such a configuration, the first terminal contact hole CHT1, the third terminal contact hole CHT3, the fourth terminal contact hole CHT4, and the fifth terminal contact hole CHT5 do not overlap each other.

In each of the configuration in which the extending line 440 is a portion of the third metal film M3, the configuration in which the extending line 440 is a portion of the second metal film M2, and the configuration in which the extending line 440 is a portion of the first metal film M1, the first interlayer insulating film 432 includes the first terminal contact hole CHT1 as illustrated in FIGS. 34 to 36. Therefore, in the producing process, the source contact hole CHS and the first terminal contact hole CHT1 can be formed in the first interlayer insulating film 432 in the fifth step described in the first embodiment. Accordingly, the number of times the first interlayer insulating film 432 is processed can be reduced similarly to the first embodiment.

### Sixth Embodiment

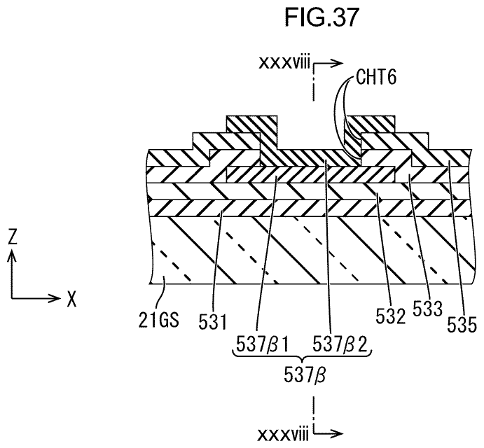

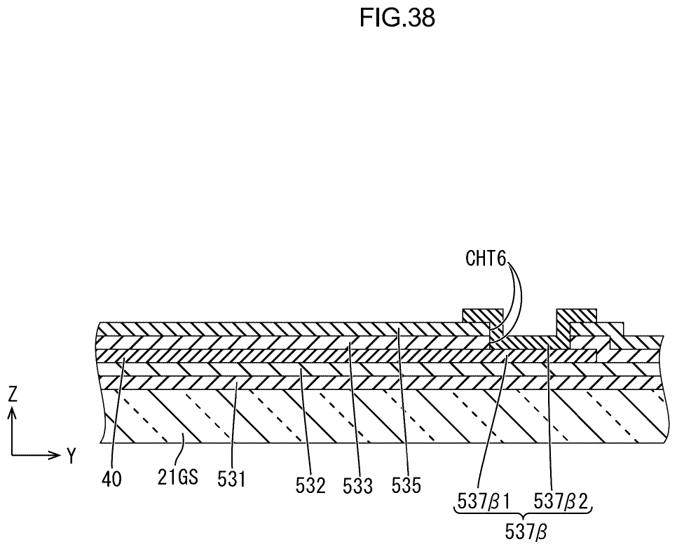

A sixth embodiment will be described with reference to FIGS. 37 and 38. The sixth embodiment has the configuration of the first embodiment and the terminal 37 includes a second terminal 537α. Configuration, operations, and effects similar to those of the first embodiment may not be described.

The terminals 37 of this embodiment include the second terminal 537β illustrated in FIGS. 37 and 38. The second terminal 537β includes a third metal film portion 537β1 (a third terminal portion) that is a portion of the third metal film M3 and a transparent electrode portion 537β2 (a fourth terminal portion) that is a portion of the second transparent electrode film. The third metal portion 537β1 is disposed in a layer upper than (above) a first interlayer insulating film 532. The transparent electrode portion 537β2 is disposed to overlap the third metal film portion 537β1 via a second interlayer insulating film 533 (the third insulating film) and a third interlayer insulating film 535. The second interlayer insulating film 533 and the third interlayer insulating film 535, which are disposed between the third metal film portion 537β1 and the transparent electrode portion 537β2, include sixth terminal contact holes CHT6 (a sixth contact hole) in portions overlapping both of the third metal film portion 537β1 and the transparent electrode portion 537β2. The sixth terminal contact hole CHT6 in the second interlayer insulating film 533 and the sixth terminal contact hole CHT6 in the third interlayer insulating film 535 communicate. The third metal film portion 537β1 and the transparent electrode portion 537β2 are connected via the sixth terminal contact holes CHT6 in the second interlayer insulating film 533 and the third interlayer insulating film 535.

Thus, in this embodiment, the sixth terminal contact holes CHT6 for connecting the third metal film portion 537β1 and the transparent electrode portion 537β2 of the second terminal 537β are formed in the second interlayer insulating film 533 and the third interlayer insulating film 535 and not formed in the first interlayer insulating film 532. Therefore, in the producing process, the first interlayer insulating film 532 need not be processed for forming the second terminal 537β in the non-display area NAA. This reduces the number of times the first interlayer insulating film 532 is processed compared to the prior method and configuration.

As previously described, the liquid crystal panel of this embodiment includes the display area AA displaying an image (refer to FIG. 1), the non-display area displaying no image (refer to FIG. 1), the TFTs 24 disposed in the display area AA (refer to FIG. 6), the upper layer lines 27B disposed in the display area AA and connected to the TFTs 24, respectively (refer to FIG. 4), the pixel electrodes 25 disposed in the display area AA and connected to the TFTs 24, respectively (refer to FIG. 6), the common electrode 28 disposed in the display area AA (refer to FIG. 4), and the second terminals 537β disposed in the non-display area NAA. The TFT 24 includes the gate electrode 24A that is a portion of the first metal film M1, the semiconductor section 24D that is a portion of the semiconductor film S1 included in a layer upper than the first metal film M1 via the gate insulating film 531, the source electrode 24B that is a portion of the second metal film M2 included in a layer upper than the semiconductor film S1 and is connected to the semiconductor section 24D, and the drain electrode 24C that is a portion of the second metal film M2 different from the portion of the second metal film M2 configured as the source electrode 24B and is connected to the semiconductor section 24D. The upper layer line 27B is a portion of the third metal film M3 disposed in a layer upper than the second metal film M2 via the first interlayer insulating film 532. A portion of the upper layer line 27B overlaps the source electrode 24B. The pixel electrode 25 includes portions of the first transparent electrode film T1 and the fourth metal film M4 (he fourth conductive film) that are included in layers upper than the third metal film M3 via the second interlayer insulating film 533 and the planarizing film 34 (the third insulating film). The pixel electrode 25 partially overlaps the drain electrode 24C and is connected to the drain electrode 24C. The common electrode 28 is a portion of the second transparent electrode film T2 (the fifth conductive film) that is included in a layer upper than the first transparent electrode film T1 and the fourth metal film M4 (the fourth conductive film) via the third interlayer insulating film 535 (the fourth insulating film). The common electrode 28 is disposed to overlap the pixel electrode 25 via the third interlayer insulating film 535. The second terminal 537β3 includes the third metal film portion 537β1 (the third terminal portion) and the transparent electrode portion 537β2 (the fourth terminal portion). The third metal film portion 537β1 is a portion of the third metal film M3 that is different from the portion of the third metal film M3 configured as the upper layer line 27B. The transparent electrode portion 537β2 is a portion of the second transparent electrode film T2 that is different from the portion of the second transparent electrode film T2 configured as the common electrode 28. At least a portion of the transparent electrode portion 537β2 overlaps the third metal film portion 537β1. The first interlayer insulating film 532 includes the source contact hole CHS (refer to FIG. 6) in a portion overlapping the upper layer line 27B and the source electrode 24B. The second interlayer insulating film 533 (the third insulating film) and the third interlayer insulating film 535 include the sixth terminal contact holes CHT6 (the sixth contact hole) in portions overlapping both of the third metal film portion 537β1 and the transparent electrode portion 537β2. The sixth terminal contact hole CHT6 in the second interlayer insulating film 533 and that in the third interlayer insulating film 535 communicate.

The TFT 24 disposed in the display area AA is driven when a potential higher than the threshold voltage is supplied to the gate electrode 24A. Then, the signal supplied to the source electrode 24B from the upper layer line 27B is supplied to the drain electrode 24C via the semiconductor section 24D. The pixel electrode 25 connected to the drain electrode 24C is charged with the potential of the supplied signal. An electric field is created between the pixel electrode 25 and the common electrode 28 that overlap via the third interlayer insulating film 535 according to the potential difference and an image is displayed with using the electric field. In the display area AA, the upper layer line 27B, which is a portion of the third metal film M3, is connected to the source electrode 24B, which is a portion of the second metal film M2, via the source contact hole CHS in the first interlayer insulating film 532. In the non-display area AA, the transparent electrode portion 537β2, which is a portion of the second transparent electrode film T2, is connected to the third metal film portion 537β1, which is a portion of the third metal film M3, via the sixth terminal contact holes CHT6 in the second interlayer insulating film 533 and the third interlayer insulating film 535. Therefore, in the producing process, the first interlayer insulating film 532 need not be processed for forming the second terminal 537β in the non-display area NAA. This reduces the number of times the first interlayer insulating film 532 is processed compared to the prior method and configuration.

### Seventh Embodiment

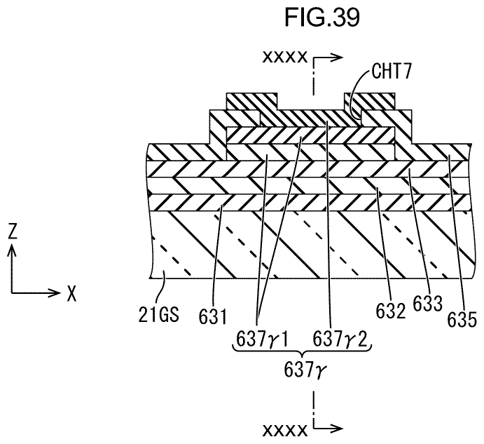

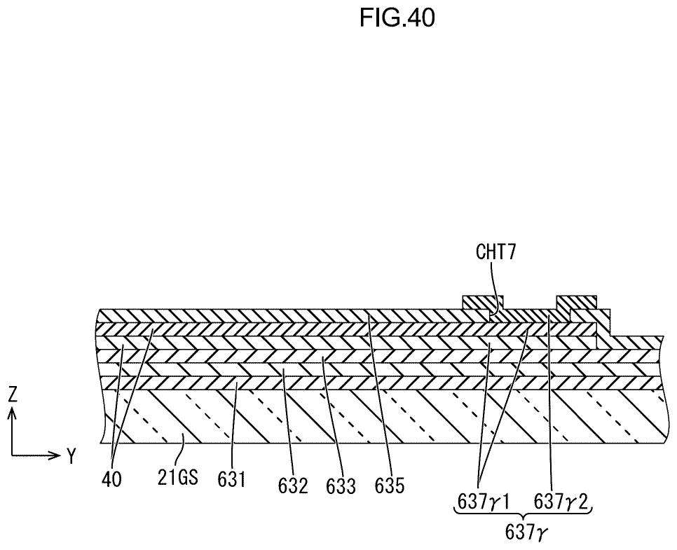

A seventh embodiment will be described with reference to FIGS. 39 and 40. In the seventh embodiment, the terminals 37 include a third terminal 637γ. Configuration, operations, and effects similar to those of the first embodiment may not be described.

In this embodiment, the terminals 37 include the third terminal 637γ illustrated in FIGS. 39 and 40. The third terminal 637γ includes a layered film portion 637γ1 (a fifth terminal portion) that includes a portion of the first transparent electrode film T1 and a portion of the fourth metal film M4 and a transparent electrode portion 637γ2 (a sixth terminal portion) that is a portion of the second transparent electrode film. The layered film portion 637γ1 is disposed above a second interlayer insulating film 633. The transparent electrode portion 637γ2 is disposed to overlap the layered film portion 637γ1 via a third interlayer insulating film 635. The third interlayer insulating film 635, which is disposed between the layered film portion 637γ1 and the transparent electrode portion 637γ2, includes a seventh terminal contact hole CHT7 (a seventh contact hole) in a portion overlapping both of the layered film portion 637γ1 and the transparent electrode portion 637γ2. The layered film portion 637γ1 and the transparent electrode portion 637γ2 are connected via the seventh terminal contact hole CHT7 in the third interlayer insulating film 635.

Thus, in this embodiment, the seventh terminal contact hole CHT7 for connecting the layered film portion 637γ1 and the transparent electrode portion 637γ2 of the third terminal 637γ is formed in the third interlayer insulating film 635 and is not formed in a first interlayer insulating film 632. Therefore, in the producing process, the first interlayer insulating film 632 need not be processed for forming the third terminal 637γ in the non-display area NAA. This reduces the number of times the first interlayer insulating film 632 is processed compared to the prior method and configuration.

As previously described, the liquid crystal panel of this embodiment includes the display area AA displaying an image (refer to FIG. 1), the non-display area displaying no image (refer to FIG. 1), the TFTs 24 disposed in the display area AA (refer to FIG. 6), the upper layer lines 27B disposed in the display area AA and connected to the TFTs 24, respectively (refer to FIG. 4), the pixel electrodes 25 disposed in the display area AA and connected to the TFTs 24, respectively (refer to FIG. 6), the common electrode 28 disposed in the display area AA (refer to FIG. 4), and the third terminals 637γ disposed in the non-display area NAA. The TFT 24 includes the gate electrode 24A that is a portion of the first metal film M1, the semiconductor section 24D that is a portion of the semiconductor film S1 included in a layer upper than the first metal film M1 via a gate insulating film 631, the source electrode 24B that is a portion of the second metal film M2 included in a layer upper than the semiconductor film S1 and is connected to the semiconductor section 24D, and the drain electrode 24C that is a portion of the second metal film M2 different from the portion of the second metal film M2 configured as the source electrode 24B and is connected to the semiconductor section 24D. The upper layer line 27B is a portion of the third metal film M3 disposed in a layer upper than the second metal film M2 via the first interlayer insulating film 632. A portion of the upper layer line 27B overlaps the source electrode 24B. The pixel electrode 25 includes portions of the first transparent electrode film T1 and the fourth metal film M4 (the fourth conductive film) that are included in layers upper than the third metal film M3 via the second interlayer insulating film 633 and the planarizing film 34 (the third insulating film). The common electrode 28 is a portion of the second transparent electrode film T2 that is included in a layer upper than the first transparent electrode film T1 and the fourth metal film M4 (the fourth conductive film) via the third interlayer insulating film 635. The common electrode 28 is disposed to overlap the pixel electrode 25 via the third interlayer insulating film 635. The third terminal 637γ includes the layered film portion 637γ1 (the fifth terminal portion) and the transparent electrode portion 637γ2 (the sixth terminal portion). The layered film portion 637γ1 includes portions of the first transparent electrode film T1 and the fourth metal film M4 different from the portions of the first transparent electrode film T1 and the fourth metal film M4 configured as the pixel electrode 25. The transparent electrode portion 637γ2 is a portion of the second transparent electrode film T2 different from the portion of the second transparent electrode film T2 configured as the common electrode 28. At least a portion of the transparent electrode portion 637γ2 overlaps the layered film portion 637γ1. The first interlayer insulating film 632 includes the source contact hole CHS (refer to FIG. 6) in a portion overlapping the upper layer line 27B and the source electrode 24B. The third interlayer insulating film 635 includes the seventh terminal contact hole CHT7 (the seventh contact hole) in a portion overlapping both of the layered film portion 637γ1 and the transparent electrode portion 637γ2.

The TFT 24 disposed in the display area AA is driven when a potential higher than the threshold voltage is supplied to the gate electrode 24A. Then, the signal supplied to the source electrode 24B from the upper layer line 27B is supplied to the drain electrode 24C via the semiconductor section 24D. The pixel electrode 25 connected to the drain electrode 24C is charged with the potential of the supplied signal. An electric field is created between the pixel electrode 25 and the common electrode 28 that overlap via the third interlayer insulating film 635 according to the potential difference and an image is displayed with using the electric field. In the display area AA, the upper layer line 27B, which is a portion of the third metal film M3, is connected to the source electrode 24B, which is a portion of the second metal film M2, via the source contact hole CHS in the first interlayer insulating film 632. In the non-display area AA, the transparent electrode portion 637γ2, which is a portion of the second transparent electrode film T2, is connected to the layered film portion 637γ1, which includes a portion of the first transparent electrode film T1 and a portion of the fourth metal film M4 (the fourth conductive film), via the seventh terminal contact hole CHT7 in the third interlayer insulating film 635. Therefore, in the producing process, the first interlayer insulating film 632 need not be processed for forming the third terminal 637γ in the non-display area NAA. This reduces the number of times the first interlayer insulating film 632 is processed compared to the prior method and configuration.

### Other Embodiments

The technology described herein is not limited to the embodiments described above and illustrated by the drawings. For example, the following embodiments will be included in the technical scope of the present technology.
(1) The first terminal 37α, 337α, 437α, the second terminal 537β, and the third terminal 637γ may be included in the terminals 37 disposed in the flexible substrate arrangement area in the non-display area NAA of the array substrate 21.
(2) The relation of the widths of the lower layer line 27A and the upper layer line 27B of the source line 27, 127 may be altered as appropriate from that illustrated in the drawings. The relation of the widths of the touch line 30, the lower layer line 27A, and the upper layer line 27B may be altered as appropriate from that illustrated in the drawings.
(3) The gate line 26, 126 may partially include wide sections and the wide sections may be configured as the gate electrodes 24A, 124A of the TFTs 24, 124, 224.
(4) The plan view shape of the gate electrode 24A, 124A, the source electrode 24B, 124B, 224B, the drain electrode 24C, 224C, and the semiconductor section 24D, 224D of the TFT 24, 124, 224 may be altered as appropriate from those illustrated in the drawings.
(5) The plan view shape of the pixel electrode 25, 225 may be altered as appropriate from that illustrated in the drawings.
(6) In the array substrate 21, the fourth metal film M4 may be included in a layer lower than the first transparent electrode film T1. In such a configuration, an insulating film may be disposed between the fourth metal film M4, which is on a lower layer side, and the first transparent electrode film T1, which is on an upper layer side. With the insulating film being disposed between the fourth metal film M4 and the first transparent electrode film T1, the touch line 30 may have a single layer structure including only the fourth metal film M4 and the pixel electrode 25, 225 may have a single layer structure including only the first transparent electrode film T1.
(7) The liquid crystal panel may not include the touch panel pattern (the touch panel function). In such a configuration, the common electrode 28 has a non-divided structure and the touch electrodes 29 are not formed. In such a configuration, instead of the touch lines 30, a common line that includes the first transparent electrode film T1 and a portion of the third metal film M3 may be included. The common line is connected to the common electrode 28 to supply a common potential signal.
(8) In the configuration of (7), the array substrate may not include the fourth metal film M4. In such a configuration, the touch line 30 and the common line may not be formed.
(9) The number and the arrangement of the drivers 12 and the flexible substrate 13 may be altered as appropriate from those illustrated in the drawings.
(10) Material of the semiconductor film included in the array substrate may be any of amorphous silicon material, oxide semiconductor material, and polycrystalline silicon material.
(11) The pixel electrode 25 may be a portion of the second transparent electrode film T2 and the common electrode 28 may be a portion of the first transparent electrode film T1. In such a configuration, the pixel electrode 25 may preferably include a slit for alignment control.
(12) The TFT 24, 124, 224 may be a top gate TFT or a double gate TFT.
(13) A gate driver may be mounted on the array substrate instead of the circuit portion 14.
(14) The driver 12 may be mounted on the flexible substrate 13 through the chip-on-film (COF) technology. The flexible substrate 13 is mounted on the array substrate through the film-on-glass (FOG) technology.
(15) The planar shape of the liquid crystal panel may be vertically elongated rectangle, a square, a circle, a semicircle, a vertically elongated oval, an oval, or a trapezoid.
(16) The display mode of the liquid crystal panel may be the TN (twisted nematic) mode, the VA (vertical alignment) mode, and the IPS (in-plane switching) mode.
(17) The liquid crystal panel may be a reflective liquid crystal panel or a semitransmissive liquid crystal panel other than the transmissive liquid crystal panel.
(18) Display panels other than the liquid crystal panel such as organic electro luminescence (EL) display panels and microcapsule-based electrophoretic display (EPD) panels may be used.

1. A display device comprising:
a display section in which an image is displayed;
a non-display section in which no image is displayed;
a switching component disposed in the display section;
a first line disposed in the display section and connected to the switching component; and
a first terminal disposed in the non-display section, wherein
the switching component includes
a first electrode that is a portion of a first conductive film,
a semiconductor section that is a portion of a semiconductor film disposed in a layer upper than the first conductive film via a first insulating film, the semiconductor section being disposed to overlap the first electrode,
a second electrode that is a portion of a second conductive film disposed in a layer upper layer than the semiconductor film, the second electrode being connected to the semiconductor section, and
a third electrode that is a portion of the second conductive film different from the portion of the second conductive film configured as the second electrode, the third electrode being connected to the semiconductor section,
the first line is a portion of a third conductive film disposed in a layer upper than the second conductive film via a second insulating film, a portion of the first line overlaps the second electrode,
the first terminal includes a first terminal portion and a second terminal portion,
the first terminal portion is a portion of the second conductive film different from portions of the second conductive film configured as the second electrode and the third electrode,
the second terminal portion is a portion of the third conductive film different from the portion of the third conductive film configured as the first line and at least a portion of the second terminal portion overlaps the first terminal portion, and
the second insulating film includes a first contact hole that overlaps the first line and the second electrode and a second contact hole that overlaps the first terminal portion and the second terminal portion.

2. The display device according to claim 1, further comprising a second line disposed in the display section, the second line being a portion of the second conductive film different from portions of the second conductive film configured as the second electrode, the third electrode, and the first terminal portion, the second line being continuous to the second electrode, and the second line extending along the first line and overlapping the first line via the second insulating film.

3. The display device according to claim 1, further comprising a third line disposed in the display section, the third line being a portion of the first conductive film different from the portion of the first conductive film configured as the first electrode, the third line being continuous to the first electrode and crossing the first line via the first insulating film and the second insulating film.

4. The display device according to claim 1, further comprising:
a fourth electrode disposed in the display section and connected to the third electrode; and
a pixel electrode disposed in the display section and connected to the fourth electrode, wherein
the fourth electrode is a portion of the third conductive film different from the portion of the third conductive film configured as the first line and at least a portion of the fourth electrode overlaps the third electrode,
the pixel electrode is a portion of a fourth conductive film that is disposed in a layer upper than the third conductive film via a third insulating film and a portion of the pixel electrode overlaps the fourth electrode,
the second insulating film includes a third contact hole that overlaps the third electrode and the fourth electrode, and
the third insulating film includes a fourth contact hole that overlaps the fourth electrode and the pixel electrode.

5. The display device according to claim 1, further comprising a pixel electrode disposed in the display section and connected to the third electrode, the pixel electrode being a portion of a fourth conductive film that is disposed in a layer upper than the third conductive film via a third insulating film and a portion of the pixel electrode overlapping the third electrode, wherein
the second insulating film and the third insulating film include a fifth contact hole that overlaps the third electrode and the pixel electrode.

6. A display device comprising:
a display section in which an image is displayed;
a non-display section in which no image is displayed;
a switching component disposed in the display section;
a first line disposed in the display section and connected to the switching component;
a pixel electrode disposed in the display section and connected to the switching component;
a common electrode disposed in the display section; and
a second terminal disposed in the non-display section, wherein
the switching component includes
a first electrode that is a portion of a first conductive film,
a semiconductor section that is a portion of a semiconductor film disposed in a layer upper than the first conductive film via a first insulating film, the semiconductor section being disposed to overlap the first electrode,
a second electrode that is a portion of a second conductive film disposed in a layer upper layer than the semiconductor film, the second electrode being connected to the semiconductor section, and
a third electrode that is a portion of the second conductive film different from the portion of the second conductive film configured as the second electrode, the third electrode being connected to the semiconductor section,
the first line is a portion of a third conductive film that is disposed in a layer upper than the second conductive film via a second insulating film, a portion of the first line overlaps the second electrode,
the pixel electrode is a portion of a fourth conductive film that is disposed in a layer upper than the third conductive film via a third insulating film and a portion of the pixel electrode overlaps the third electrode and the pixel electrode is connected to the third electrode,
the common electrode is a portion of a fifth conductive film that is disposed in a layer upper than the fourth conductive film via a fourth insulating film and the common electrode overlaps the pixel electrode via the fourth insulating film,
the second terminal includes a third terminal portion and a fourth terminal portion,
the third terminal portion is a portion of the third conductive film different from the portion of the third conductive film configured as the first line,
the fourth terminal portion is a portion of the fifth conductive film different from the portion of the fifth conductive film configured as the common electrode and at least a portion of the fourth terminal portion overlaps the third terminal portion,
the second insulating film includes a first contact hole that overlaps the first line and the second electrode, and
the third insulating film and the fourth insulating film include a sixth contact hole that overlaps the third terminal portion and the fourth terminal portion.

7. A display device comprising:
a display section in which an image is displayed;
a non-display section in which no image is displayed;
a switching component disposed in the display section;
a first line disposed in the display section and connected to the switching component;
a pixel electrode disposed in the display section and connected to the switching component;
a common electrode disposed in the display section; and
a third terminal disposed in the non-display section, wherein
the switching component includes
a first electrode that is a portion of a first conductive film,
a semiconductor section that is a portion of a semiconductor film disposed in a layer upper than the first conductive film via a first insulating film, the semiconductor section being disposed to overlap the first electrode,
a second electrode that is a portion of a second conductive film disposed in a layer upper layer than the semiconductor film, the second electrode being connected to the semiconductor section, and
a third electrode that is a portion of the second conductive film different from the portion of the second conductive film configured as the second electrode, the third electrode being connected to the semiconductor section,
the first line is a portion of a third conductive film disposed in a layer upper than the second conductive film via a second insulating film, a portion of the first line overlaps the second electrode,
the pixel electrode is a portion of a fourth conductive film that is disposed in a layer upper than the third conductive film via a third insulating film,
the common electrode is a portion of a fifth conductive film that is disposed in a layer upper than the fourth conductive film via a fourth insulating film and the common electrode overlaps the pixel electrode via the fourth insulating film,
the third terminal includes a fifth terminal portion and a sixth terminal portion,
the fifth terminal portion is a portion of the fourth conductive film different from the portion of the fourth conductive film configured as the pixel electrode,
the sixth terminal portion is a portion of the fifth conductive film different from the portion of the fifth conductive film configured as the common electrode and at least a portion of the sixth terminal portion overlaps the fifth terminal portion,
the second insulating film includes a first contact hole that overlaps the first line and the second electrode, and
the fourth insulating film includes a seventh contact hole that overlaps the fifth terminal portion and the sixth terminal portion.

8. A method of producing a display device comprising:
forming a first conductive film;
patterning the first conductive film to form a first electrode in a display section in which an image is displayed;
forming a first insulating film in a layer upper than the first conductive film;
forming a semiconductor film in a layer upper than the first insulating film;
patterning the semiconductor film to form a semiconductor section that overlaps the first electrode;
forming a second conductive film in a layer upper than the semiconductor film;
patterning the second conductive film to form a second electrode connected to the semiconductor section and a third electrode connected to the semiconductor section and form a first terminal portion in a non-display section in which no image is displayed;
forming a second insulating film in a layer upper than the second conductive film;
patterning the second insulating film to form a first contact hole that overlaps the second electrode and a second contact hole that overlaps the first terminal portion;
forming a third conductive film in a layer upper than the second insulating film; and
patterning the third conductive film to form a first line in the display section such that a portion of the first line overlaps the second electrode and the first contact hole and to form a second terminal portion in the non-display section such that at least a portion of the second terminal portion overlaps the first terminal portion and the second contact hole, and the second terminal portion and the first terminal portion being configured as a first terminal.
